(19) United States
(12) Patent Application Publication
(10) Pub. No.: US 2025/0151314 A1
(43) Pub. Date: May 8, 2025

(54) MICROELECTRONIC DEVICE COMPRISING A WRAPPING GRID AND METHOD FOR PRODUCING SUCH A DEVICE

(71) Applicant: COMMISSARIAT A L'ENERGIE ATOMIQUE ET AUX ENERGIES ALTERNATIVES, Paris (FR)

(72) Inventor: Sylvain BARRAUD, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 18/799,537

(22) Filed: Aug. 9, 2024

(30) Foreign Application Priority Data
Aug. 11, 2023 (FR) 2308690

(51) Int. Cl. H10D 30/47; H10D 30/00; H10D 30/01; H10D 62/80; H10D 64/23

(52) U.S. Cl. CPC H10D 30/481; H10D 30/017; H10D 30/0191; H10D 30/502; H10D 62/875; H10D 62/882; H10D 62/883; H10D 64/256

(57) ABSTRACT

The invention relates to a device comprising transistors (T1, T2, T3), each comprising:
a channel (41) with the basis of a semiconductive material,
a gate-all-around (50), totally surrounding said channel (41),
a source (42) and a drain (43) on either side of the channel (41), and source and drain contacts (60S, 60, 60D),
a gate dielectric layer (30) separating the channel (41) and the gate-all-around (50),
spacers (70) on either side of the gate (50). Advantageously, the gate dielectric layer (30) and the spacers (70) are formed by at least one single and same continuous layer (73) surrounding the gate-all-around (50). The invention also relates to a method for producing such a device.

### TECHNICAL FIELD

The invention relates to the field of microelectronic technologies. It has a particularly advantageous application in manufacturing advanced gate-all-around and semiconductive material-based channel FET (Field-Effect Transistor)-type devices, such as two-dimensional (2D) materials or semiconductive oxides.

### PRIOR ART

The constant increase of performance of transistors has first been made possible by reducing transistor dimensions, for a conventional silicon-based MOSFET (Metal-Oxide-Semiconductor Field-Effect Transistor) architecture.

This conventional architecture has then given way to other types of architectures, better adapted to performances specified in technology nodes less than 12 nm. The so-called “finFET” architecture makes it possible, for example, to respond to the performances set by 7 nm and 5 nm technology nodes.

For the next technology nodes, in particular, from 3 nm, other architectures offering an improved gate confinement are necessary. An architecture considered to respond to the problems of these next technology nodes comprises so-called GAA (Gate-All-Around) transistors comprising channels stacked on one another, surrounded by a common gate.

Such an architecture typically comprises a plurality of stacked transistors, each transistor comprising:
a channel with the basis of a semiconductive material,
a so-called gate-all-around, totally surrounding said channel,
a source and a drain on either side of the channel, and source and drain contacts connected respectively to the source and to the drain,
a gate dielectric layer separating the channel and the gate which is a totally gate-all-around,
spacers on either side of the gate, configured to electrically isolate the gate with respect to the source and drain contacts.

Such an architecture is typically obtained by structuration of a stack of two types of alternating layers, where one of the types of layers comprises semiconductive layers intended to form the transistor channels, and the other of the types of layers comprises sacrificial layers intended to be replaced with the gate-all-around.

To reduce the dimensions of the transistors and to improve the compactness and the integration, while limiting the interfering capacities in this device architecture, a solution consists of forming “internal” spacers. These internal spacers are formed in the sacrificial layers, between the semiconductive layers, as illustrated, for example, in the document, “N. Loubet et al., 2017 Symposium on VLSI Technology Digest of Technical Papers”. A difficulty linked to the manufacturing of these architectures relates to the dimensional control of the internal spacers. The partial removal of the sacrificial layers to form the internal spacers remains poorly controlled. A variability of the dimensions of the internal spacers in the stack of the layers is observed. It is further difficult to align these internal spacers with respect to gate patterns defined during the structuration of the stack.

A controlled industrial manufacture, satisfying the required quality requirements, is a significant challenge for the development of GAA transistor technologies.

There is therefore a need for a method for manufacturing GAA transistors having an improved reproducibility and a limited manufacturing cost.

An aim of the invention is to propose such a reproducible manufacturing method, controlled and limiting the manufacturing cost. Another aim of the invention is to propose a device having an architecture being able to be reproduced more easily and with more control. Another aim of the invention is to overcome at least partially the disadvantages of known methods and devices.

### SUMMARY To achieve these aims, according to an embodiment, a microelectronic device is provided, comprising at least one transistor comprising:

at least two channels stacked along a main direction z, each channel being with the basis of a semiconductive material,
a so-called gate-all-around, totally surrounding at least one of said channels, and preferably several channels,
a source and a drain on either side of each channel, and source and drain contacts connected respectively to the source and to the drain,
a gate dielectric layer separating each channel and the gate-all-around,
spacers on either side of the gate, configured to electrically isolate the gate with respect to the source and drain contacts.

Advantageously, the gate dielectric layer and the spacers are formed at least by one same continuous layer surrounding the gate-all-around.

Such a device architecture does not require to implement a partial removal of sacrificial layers to form spacers, contrary to the known architectures, based on “internal” spacers.

In this architecture, one single and same continuous layer forms both the spacers and the gate dielectric layer. Typically, the vertical portions of this continuous layer correspond to the spacers and the horizontal portions of this continuous layer correspond to the gate dielectric layer. The thickness of the continuous layer can be advantageously precisely controlled. It is significantly simpler to obtain a precise control over the thickness of a layer, in this case, the continuous layer, than obtaining a precise control over a partial layer removal, as considered in the prior art. The dimensional control of the spacers of the device is therefore significantly improved. The spacers are further advantageously self-aligned with respect to the gate which is a totally gate-all-around.

Another aspect of the invention relates to a method for manufacturing a microelectronic device, comprising the following steps:
Providing on a substrate, a stack along the main direction z comprising a first plurality of first layers made of a first material alternated with a second plurality of second layers made of a second material, the first and second materials being different from said semiconductive material,
Forming, in this stack, first openings defining first patterns,
Forming sacrificial gates mounted on the first patterns and partially in the first openings,
Forming, in the first patterns, second openings defining second patterns,
Totally removing, from the second openings, the first material of the first layers, so as to form first spaces,
Removing the sacrificial gates, so as to form third openings,
Totally removing, from the third openings, the second material of the second layers, so as to form second spaces,
Depositing a continuous layer, with the basis of a dielectric material, around the second layers or in the second spaces, so as to form:
   A gate dielectric layer from the horizontal parts of the continuous layer,
   Spacers from the vertical parts of the continuous layer,
After formation of the continuous layer, depositing a layer with the basis of a semiconductive material in the first spaces, so as to form:
   channels with the basis of the semiconductive material, and
   sources and drains with the basis of the semiconductive material on either side of the channels,
After formation of the continuous layer, filling with a material, called gate material, the second spaces, so as to form the so-called gates-all-around, totally surrounding at least one of the channels of the at least one transistor.

A principle of the method according to the invention consists of forming a continuous layer comprising both the spacers and the gate dielectric layer. This continuous layer can be formed around the second layers, when the method is typically of the “gate last” type (the replacement of the sacrificial gates with functional gates is done after the formation of the transistor channels). Alternatively, the continuous layer can be formed in the second spaces, when the method is typically of the “gate first” type (the replacement of the sacrificial gates with functional gates is done before the formation of the transistor channels). The advantages mentioned above in the scope of the device for the continuous layer apply mutatis mutandis to the method. The continuous layer can, in particular, be deposited by precisely controlling its thickness, at the vertical parts and at the horizontal parts. The continuous layer can, for example, be deposited in a conform manner.

Another principle of the method according to the invention consists of selectively replacing certain layers of the initial stack with a semiconductive material, in order to form the transistor channels. The initial stack does not comprise the semiconductive material. The subsequent deposition of the semiconductive material aims to better preserve the semiconductive material. According to a preferred option, the semiconductive material is a two-dimensional (2D) material chosen from among MX2 transition metal dichalcogenides with M taken from among molybdenum (Mo) or tungsten (W), and X taken from among sulphur(S) or selenium (Se).

Thus, the method according to the invention makes it possible to introduce 2D material layers after structuration of the stack. This advantageously makes it possible to limit the risk of degrading the 2D material during the method. The 2D material is not exposed to all the steps of the manufacturing method. The 2D material is thus preserved.

Furthermore, the late introduction of the 2D material during the manufacturing method makes it possible to use standard microelectronic technologies for the formation and the structuration of the stack. It is not necessary to modify or adapt the standard structuration technological steps to the use constraints of the 2D material. The costs of the method are thus advantageously limited. The method can further be more easily implemented in current production lines.

Other aims, features and advantages of the present invention will appear upon examining the description below and the accompanying drawings. It is understood that other advantages can be incorporated.

### BRIEF DESCRIPTION OF THE FIGURES

FIGS. 1A, 2A, 3A, 4A, 5A, 6A, 7A, 8A, 9A, 10A, 11A, and 12A schematically illustrate, along transverse cross-sections xz of the steps of manufacturing a superposed transistor device, according to a first embodiment of the present invention.

FIGS. 1B, 2B, 3B, 4B, 5B, 6B, 7B, 8B, 9B, 10B, 11B, and 12B schematically illustrate, along transverse cross-sections yz indicated in corresponding figures, the same steps of manufacturing the device, according to a first embodiment of the present invention.

FIGS. 13A, 14A, 15A, 16A, 17A, 18A, 19A, and 20A schematically illustrate, along transverse cross-sections xz of the steps of manufacturing a superposed transistor device, according to a second embodiment of the present invention.

FIGS. 13B, 14B, 15B, 16B, 17B, 18B, 19B, and 20B schematically illustrate, along transverse cross-sections yz indicated in corresponding figures, the same steps of manufacturing the device, according to a second embodiment of the present invention.

FIGS. 21A, 22A, 23A, 24A, 25A, 26A, 27A, 28A, 29A, 30A, and 31A schematically illustrate, along transverse cross-sections xz of the steps of manufacturing a superposed transistor device, according to a third embodiment of the present invention.

FIGS. 21B, 22B, 23B, 24B, 25B, 26B, 27B, 28B, 29B, 30B, and 31B schematically illustrate, along transverse cross-sections yz indicated in corresponding figures, the same steps of manufacturing the device, according to a third embodiment of the present invention.

The first and second embodiments provide the replacement of sacrificial gates after formation of the transistor channels. They typically correspond to so-called “gate last” embodiments (the gate is formed last). The third embodiment provides the replacement of the sacrificial gates before formation of the transistor channels. It typically corresponds to a so-called “gate first” embodiment (the gate is formed first).

In the figures in transverse cross-sections, cutting planes are indicated (A-A′, B-B′, . . . , P-P′, . . . , Z-Z′, α-α′, . . . , ε-ε′) with references crossed with the cutting planes of the corresponding figures. The drawings are given as examples and are not limiting of the invention. They constitute principle schematic representations intended to facilitate the understanding of the invention and are not necessarily to the scale of practical applications.

In particular, in the principle diagrams, the thicknesses and/or the dimensions of the different layers, patterns and raised elements are not representative of reality. For reasons of clarity, all of the alphanumerical references are not systematically repeated from one figure to another. It is understood that the elements already described and referenced, when they are reproduced in another figure, typically have the same alphanumerical references, even if these are not explicitly mentioned. A person skilled in the art will identify, without difficulties, one same element reproduced in different figures.

### DETAILED DESCRIPTION

Before starting a detailed review of embodiments of the invention, optional features are stated below which can optionally be used in association or alternatively:

According to an example, the stack comprises an alternance of a first layer of the first plurality with a second layer of the second plurality. Preferably, said first layer and said second layer are in contact. According to an example, the final device comprises transistor channels formed after selective removal of the first layers from the initial stack. According to an example, the final device comprises gates-all-around formed after selective removal of the second layers from the initial stack. The initial stack does not typically comprise neither the semiconductive material of the transistor channels, nor the material of the gates-all-around.

According to an example, the continuous layer has so-called horizontal parts, extending into a plane perpendicular to the main direction z and so-called vertical parts, extending into planes parallel to the main direction z, and the gate dielectric layer corresponds to the horizontal parts of the continuous layer, and the spacers correspond to the vertical parts of the continuous layer.

According to an example, the vertical parts of the continuous layer, intended to form the spacers, have a thickness which is different from that of the horizontal parts of the continuous layer, intended to form the gate dielectric layer.

According to another example, the deposition of the continuous layer is conform and the vertical and horizontal parts have substantially the same thickness.

According to an example, the continuous layer has a substantially constant thickness. According to an example, the continuous layer comprises a plurality of continuous layers superposed on one another.

According to an example, the spacers formed from the continuous layer are directly in contact with the layer with the basis of the semiconductive material, without additional spacer inserted between said layer and the continuous layer.

According to an example, the totally gate-all-around is common to all the channels of the at least one transistor, said gate having an upper part flanked by additional spacers without continuity with the gate dielectric layer. These additional spacers are typically directly in contact with the flanks of the gate-all-around. These additional spacers make it possible to reduce the interfering capacities in the device.

According to an example, the source and the drain are common to all the channels of the at least one transistor.

According to an example, the deposition of the layer with the basis of the semiconductive material is configured to form vertical layer portions with the basis of the semiconductive material on the flanks of the second pattern and horizontal layer portions with the basis of the semiconductive material in the first spaces. This makes it possible to facilitate the return of the source and drain contacts in the device.

According to an example, the vertical portions of the layer with the basis of the semiconductive material are thicker than the horizontal portions. Thicker vertical portions make it possible to decrease the contact resistance of the source and drain contacts.

According to an example, the method comprises a formation of source and drain contacts in the second openings, after deposition of the layer with the basis of the semiconductive material.

According to an example, the formation of the gates-all-around is done after the deposition of the layer with the basis of the semiconductive material. This type of method called “gate last”, where the functional gate is formed at the end of the method in replacement of a sacrificial gate, makes it possible to preserve the dimensional features of the functional gate. The thermal budget linked to the deposition of the semiconductive material does not impact the equivalent gate oxide thickness at the interface with the gate. The structural and electrical features of the functional gate are better controlled.

According to an example, the removal of the sacrificial gates and the removal of the second material from the second layers are done after deposition of the layer with the basis of the semiconductive material. According to an example, the deposition of the at least one continuous layer is done around second layers.

According to an example, the removal of the first material from the first layers is done selectively at the second material of the second layers.

According to an example, the method further comprises, before formation of the second openings, a formation of additional spacers on the first patterns and bordering the sacrificial gates.

According to an example, the method is a “gate last”-type method, and comprises the steps below, sequenced in the following order:
Providing, on a substrate, the stack along the main direction z comprising the first plurality of first layers made of a first material alternated with the second plurality of second layers made of a second material, the first and second material being different from the semiconductive material,
Forming, in this stack, the first openings defining the first patterns,
Forming the sacrificial gates mounted on the first patterns and partially in the first openings,
Forming, in the first patterns, the second openings defining the second patterns,
Totally removing, from the second openings, the first material of the first layers, so as to form the first spaces,
Depositing the continuous layer, with the basis of a dielectric material, around the second layers, so as to form:
   the gate dielectric layer from the horizontal parts of the continuous layer,
   the spacers from the vertical parts of the continuous layer,
Depositing the layer with the basis of a semiconductive material on the continuous layer, in the first spaces, so as to form:
   channels with the basis of the semiconductive material, and
   sources and drains with the basis of the semiconductive material on either side of the channels,
Removing the sacrificial gates so as to form the third openings,
Totally removing, from the third openings, the second material of the second layers, so as to form the second spaces,
Filling the second spaces with the gate material, so as to form the gates-all-around, totally surrounding at least one channel of the at least one transistor.

According to an example, the removal of the sacrificial gates and the removal of the second material from the second layers are done before deposition of the layer with the basis of the semiconductive material. According to an example, the deposition of the at least one continuous layer is done in the second spaces.

According to an example, the method further comprises, after formation of the second openings, a deposition of at least one holding layer in said second openings, on exposed flanks of the first and second layers.

According to an example, the method further comprises, after filling of the second spaces with the gate material, a removal of the at least one holding layer, so as to expose the flanks of the first layers.

According to an example, the method is a “gate first”-type method, and comprises the steps below, sequenced in the following order:
Providing, on a substrate, the stack along the main direction z comprising the first plurality of first layers made of a first material alternated with the second plurality of second layers made of a second material, the first and second materials being different from the semiconductive material,
Forming, in this stack, the first openings defining the first patterns,
Forming the sacrificial gates mounted on the first patterns and partially in the first openings,
Forming, in the first patterns, the second openings defining the second patterns,
Forming the holding layer in said second openings, on exposed flanks of the first and second layers,
Removing the sacrificial gates, so as to form the third openings,
Totally removing, from the third openings, the second material of the second layers, so as to form the second spaces,
Depositing the continuous layer, with the basis of a dielectric material, in the second spaces, so as to form:
   the gate dielectric layer from the horizontal parts of the continuous layer,
   the spacers from the vertical parts of the continuous layer,
Filling the second spaces with the gate material, so as to form the gates-all-around,
Removing the holding layer, so as to expose the flanks of the first layers,
Totally removing, from the second openings, the first material of the first layers, so as to form the first spaces,
Depositing the layer with the basis of a semiconductive material on the continuous layer, in the first spaces, so as to form:
   channels with the basis of the semiconductive material, and
   sources and drains with the basis of the semiconductive material on either side of the channels.

According to an example, the deposition of the continuous layer is done by chemical vapour deposition or by atomic layer deposition. Chemical vapour depositions are easy to implement. Atomic layer depositions make it possible to precisely control the thickness of the continuous layer with the basis of the dielectric material.

According to an example, the deposition of the layer with the basis of the semiconductive material is done by chemical vapour deposition or by atomic layer deposition. Chemical vapour depositions are easy to implement. Atomic layer depositions make it possible to precisely control the thickness of the layer with the basis of the semiconductive material.

According to an example, the semiconductive material is chosen from among MX2 transition metal dichalcogenides with M taken from among molybdenum (Mo) or tungsten (W), and X taken from among sulphur(S), selenium (Se) or tellurium (Te).

According to another example, the semiconductive material is chosen with the basis of a semiconductive oxide, for example, IGZO (indium gallium zinc oxide)-, In2O3-, IWO (tungsten-doped indium oxide)-, ITO (indium tin oxide)-, IAZO (indium aluminium zinc oxide)-, InGaZnO-, InGaO-, InZnO-based, or an amorphous semiconductive oxide.

According to an example, the first material is chosen as SiGe and the second material is chosen as Si, or vice versa. These materials can be easily epitaxially grown by conventional microelectronic technological methods. This makes it possible to benefit from current technological methods. The cost of the method is reduced.

According to an example, the formation of the sacrificial gates is done, such that the sacrificial gates extend over an entire height of the first openings. According to an example, the first openings extend along the entire height of the stack of the first and second layers. The sacrificial gates extend over the entire height of the stack. The sacrificial gates typically bear on the substrate. This makes it possible to give an access to all the layers of the stack via the third openings, during the removal of the sacrificial gates.

According to an example, the deposition of the layer with the basis of the semiconductive material is configured, such that the layer with the basis of the semiconductive material totally fills the first spaces.

According to another example, the deposition of the layer with the basis of the semiconductive material is configured, such that the layer with the basis of the semiconductive material partially fills the first spaces. According to an example, the method further comprises, after deposition of the layer, with the basis of the semiconductive material, a deposition of a dielectric layer configured to fill the first spaces. This makes it possible to form a layer with the basis of the thin semiconductive material, without constraint over the thickness of the first layers of the initial stack. The layer with the basis of the semiconductive material can have a thickness less than that of the first layers of the initial stack.

According to an example, the substrate is a silicon-based bulk substrate.

According to an example, the stack comprises at least three first layers of the first material alternated with three second layers of the second material.

According to an example, the stack comprises as many first layers of the first material as second layers of the second material.

According to an example, the removal of the first material from the first layers selectively at the second material of the second layers is done by a first selective etching having a selectivity S_{10:20} of at least 5:1, preferably at least 10:1. This first selective etching is typically stopped at the time.

According to an example, the removal of the second material from the second layers selectively at the first material of the first layers is done by a second selective etching having a selectivity S_{20:10} of at least 5:1, preferably at least 10:1.

Unless incompatible, it is understood that all of the optional features above can be combined so as to form an embodiment which is not necessarily illustrated or described. Such an embodiment is clearly not excluded from the invention. The features and the advantages of an aspect of the invention, for example, the device or the method, can be adapted mutatis mutandis to the other aspect of the invention.

The invention is generally based on a GAA transistor microelectronic device and a method for manufacturing this device. Such a microelectronic device can have a “GAA stacked nanosheet”-type architecture, i.e. with stacked nanosheets and totally gate-all-around. A stacked nanowire and totally gate-all-around architecture is also possible.

The nanowires or nanosheets typically each comprise a conduction channel of a transistor. These channels are stacked along a direction z. This means that they each occupy a given altitude level along the direction z. A level can be defined between two planes perpendicular to the direction z.

Advantageously, the method according to the invention can be implemented to produce MOS GAA transistors for 5 nm and sub −5 nm technology nodes.

A microelectronic device comprising superposed GAA transistors can be advantageously integrated in logic systems having 3D architectures. These transistors can, in particular, be associated with other structural or functional elements so as to design complex systems.

A particular aspect of the invention relates to the implementation of 2D materials to produce the nanowires or nanosheets of the device.

The 2D materials typically correspond to compounds having a lamellar structure constituted of two-dimensional sheets, stacked along the crystallographic axis c. The atomic bonds within each sheet are strong, of covalent nature. The bonds between sheets are a lot weaker, of the Van der Waals type. These two-dimensional sheets are also called monolayers.

In the scope of the present invention, the monolayers are preferably semiconductive monolayers of the MX2 type, where M is molybdenum (Mo) or tungsten (W) and X, sulphur (S) or selenium (Se). Each “monolayer” is, in this case, composed of a metal cation plane M inserted between two anion planes X. A monolayer therefore comprises, in this case, typically three atomic planes: the atoms of the transition metal (Mo or W) form a plane sandwiched between the chalcogen planes (S, Se or Te, for example). Each transition metal atom is connected to six chalcogen atoms. These anions are in prismatic trigonal coordination with respect to the metal atoms. The MX2 transition metal dichalcogenide monolayers have a hexagonal atomic array.

The MX2 transition metal dichalcogenide monolayers are preferably MoS2, MoSe2,MoTe2, WS2, WSe2 molybdenum disulphide-based.

An alternative option relates to the implementation of semiconductive oxides to produce the nanowires or nanosheets of the device. These semiconductive oxides are preferably IGZO (indium gallium zinc oxide)-, In2O3-, IWO (tungsten-doped indium oxide)-, InGaZnO-, InGaO-, InZnO-, IAZO- or ITO (indium tin oxide)-based. Another option relates to the implementation of graphene, hexagonal boron nitride “h-BN”, phosphorene (also called “Black Phosphorus” BP), in particular, in the form of a monolayer.

It is specified that, in the scope of the present invention, the terms “on”, “surmounts”, “covers”, “underlying”, “opposite” and their equivalents do not necessarily mean “in contact with”. Thus, for example, the deposition or the application of a first layer on a second layer, does not compulsorily mean that the two layers are directly in contact with one another, but means that the first layer covers at least partially the second layer by being either directly in contact with it, or by being separated from it by at least one other layer or at least one other element.

By a substrate, a film, a layer “with the basis” of a material A, this means a substrate, a film, a layer comprising this material A only or this material A and optionally other materials, for example, doping elements or alloy elements. Thus, a silicon nitride SiN-based spacer can, for example, comprise non-stoichiometric silicon nitride (SIN), or stoichiometric silicon nitride (Si3N4), or also a silicon oxy-nitride (SiON).

By a “continuous” layer, this means a layer having a material continuity. Typically, the continuous layer coats the second layers of the second patterns, or covers the second spaces of the second patterns.

The word “dielectric” qualifies a material, the electrical conductivity of which is sufficiently low in the given application to serve as an isolator. In the present invention, a dielectric material preferably has a dielectric constant less than 20. In the present invention, the dielectric layer can have ferroelectric properties.

Several embodiments of the invention implementing successive steps of the manufacturing method are described below. Unless explicitly mentioned, the adjective “successive” does not necessarily imply, even if this is generally preferred, that the steps follow one another immediately, intermediate steps being able to separate them.

Moreover, the term “step” means the carrying out of some of the method, and can mean a set of substeps.

Moreover, the term “step” does not compulsorily mean that the actions carried out during a step are simultaneous or immediately successive. Certain actions of a first step can, in particular, be followed by actions linked to a different step, and other actions of the first step can then be resumed. Thus, the term “step” does not necessarily mean single and inseparable actions over time and in the sequence of phases of the method.

By “selective etching with respect to” or “etching having a selectivity with respect to”, this means an etching configured to remove a material A or a layer A with respect to a material B or a layer B, and having an etching speed of the material A greater than the etching speed of the material B. The selectivity is the ratio between the etching speed of the material A over the etching speed of the material B. It is referenced SAB. A selectivity S_{A:B} of 10:1 means that the etching speed of the material A is 10 times greater than the etching speed of the material B.

The different patterns formed during the manufacturing steps typically have a structure intended to evolve during the steps of the method. Thus, the patterns can comprise the sacrificial layers of the initial stack, the 2D material—or semiconductive oxide-based layers, the dielectric layers, continuous or discontinuous. The different patterns aim to form, at the end of the method, “transistor patterns”, each comprising at least one conduction channel and one gate surrounding said channel, one dielectric barrier separating the gate and the channel, one source and one drain on either side of the channel. The assignment of the first and second layers in the initial stack can be inverted.

A preferably orthonormal system, comprising the axes x, y, z is represented in the accompanying figures.

In the present patent application, thickness will preferably be referred for a layer or a film, and height will preferably be referred to for a device or a structure. The thickness is taken along a direction normal to the main extension plane of the layer or of the film. Thus, a superficial silicon (topSi) layer typically has a thickness along z. A gate pattern formed on such a superficial layer has a height along z. The relative terms “on”, “surmounts”, “under”, “underlying” refer to positions taken along the direction z. The terms “vertical”, “vertically” refer to orientations along the direction z. A vertical portion typically extends along a plane comprising the direction z. The terms “horizontal”, “horizontally” refer to orientations perpendicular to the direction z. A horizontal portion typically extends along a plane xy perpendicular to the direction z. A “lateral” dimension corresponds to a dimension along a direction of the plane xy. By a “lateral” extension, this means an extension along one or more directions of the plane xy.

An element located “in vertical alignment with” or “to the right of” another element means that these two elements are both located on one same line perpendicular to a plane into which a lower or upper face of a substrate mainly extends, i.e. on one same line oriented vertically in the figures in transverse cross-section.

The terms “substantially”, “about”, “around” mean plus or minus 10%, and preferably plus or minus 5%. Moreover, the terms “between . . . and . . . ” and equivalents mean that the limits are included, unless mentioned otherwise.

The description below has examples of implementation of the method according to the invention in a context of developing a complex 3D device. The scope of this description is clearly not limiting of the invention.

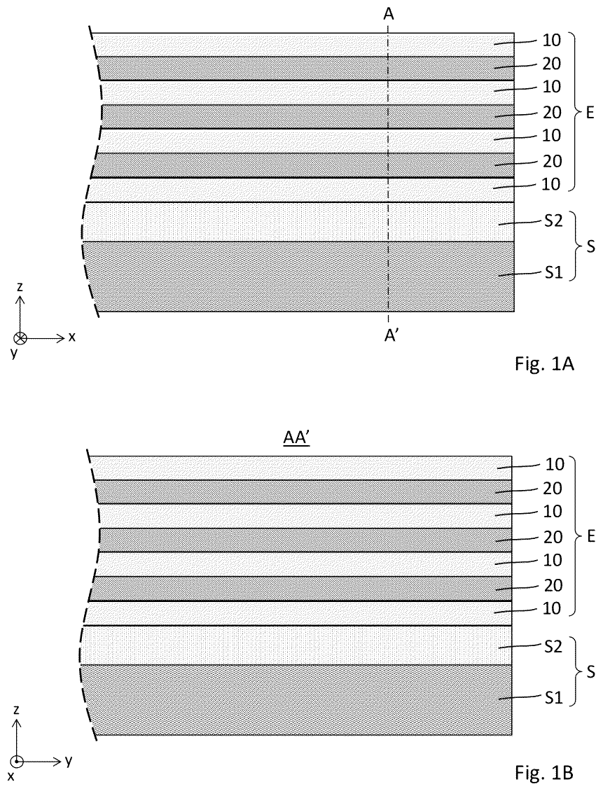

FIGS. 1A, 1B to 12A, 12B schematically illustrate steps of manufacturing a device comprising GAA transistors according to a first embodiment. Figures nA (n=1 . . . 12) correspond to first transverse cross-sections, each illustrating a different step of the manufacturing method. Figures nB (n=1 . . . 12) correspond to second transverse cross-sections, each illustrating the same step as corresponding figure nA.

As illustrated in FIGS. 1A, 1B, a first step consists of producing a stack E of semiconductive layers 10, 20 on a substrate S. The substrate S can be an SOI (silicon on insulator)-, GeOI (germanium on insulator)-, or SGOI (silicon-germanium on insulator)-type substrate. These known substrates comprise, according to common terminology for a person skilled in the art, a thick silicon layer S1 called “Si bulk”, a silicon oxide layer S2 called “BOX” (buried oxide) and a superficial thin layer, respectively silicon-, germanium- or silicon-germanium-based. This superficial thin layer can advantageously correspond to the first layer 10 of the stack E.

Alternatively, the substrate S can be an “Si bulk” bulk substrate.

The stack E comprises, according to an example, an alternance of silicon-germanium (SiGe) first layers 10 and of silicon (Si) second layers 20.

The concentration of Ge in the SiGe alloy can be 20%, 30% or 45%, for example. This concentration of germanium is chosen, so as to enable a good selectivity of the etching of SiGe with respect to Si, during selective etching steps. The greater the concentration of Ge will be, the greater the selectivity to Si will be during the subsequent removal of SiGe. This stack E is advantageously formed by epitaxy of the SiGe 10 and Si 20 layers. This step of forming the stack E is inexpensive and well-known to a person skilled in the art. The thicknesses of the Si and SiGe layers can be typically around 10 nm, and more generally between 5 nm and 20 nm, for example. In a known manner, in order to avoid the formation of structural defects, the maximum thicknesses permitted for the SiGe layers 10 depend, in particular, on the concentration of Ge chosen.

In the example illustrated in FIGS. 1A, 1B, four SiGe layers 10 are alternated with three epitaxially grown Si layers 20. An Si/SiGe super array is thus obtained. The number of Si and SiGe layers can naturally be increased. This ultimately makes it possible to increase the number of transistors stacked in the final device.

Generally, the first material of the first layers 10 and the second material of the second layers 20 are chosen such that one can be etched selectively with respect to the other. Thus, other pairs of first and second materials are possible. By respecting this etching selectivity condition, the first and second materials can be chosen from among dielectric materials (oxides and nitrides, for example), semiconductive materials, metal materials.

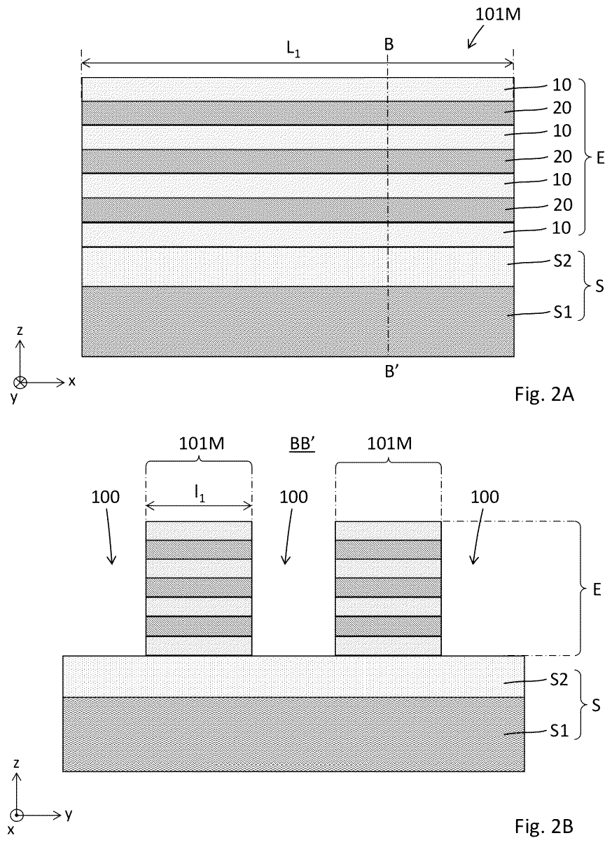

As illustrated in FIGS. 2A, 2B, a conventional lithography/etching step is carried out, in order to define first patterns 101M, and first openings 100. The etching is anisotropic and directed along z. It is configured to etch the stack E, in this case, the Si/SiGe super array, over its entire height, by stopping on the substrate S, in this case, the BOX S2. It can be done by plasma by using an HBr/O2 etching chemistry. The first patterns 101M can have a length L₁ along x of between 10 nm and 500 nm. They preferably have a width I₁ along y of between 10 nm and 120 nm, for example, of around 40 nm. This first structuration of the stack E in the form of fins, makes it possible to define a plurality of superposed nanowires or nanosheets.

For clarity, the following figures iB (i=3 . . . 12) only illustrate one single “fin” pattern 101M.

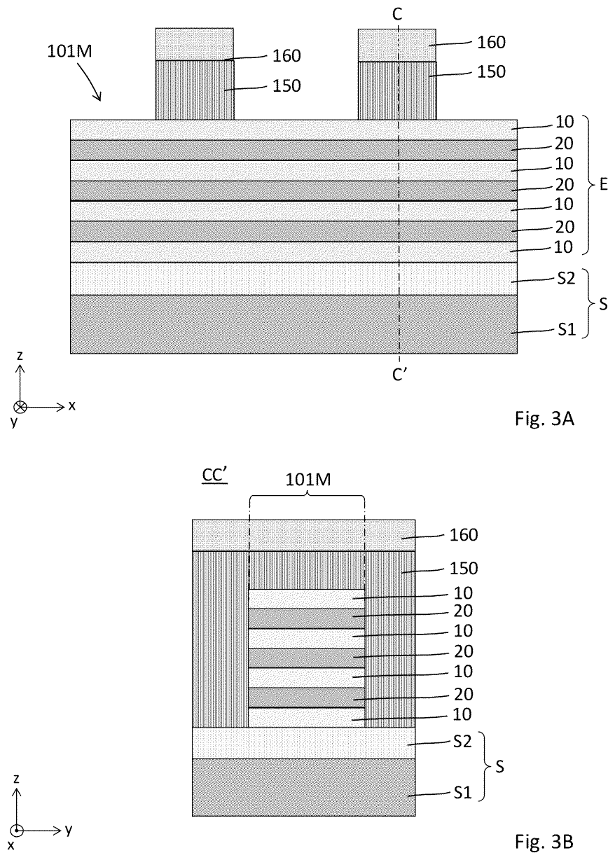

As illustrated in FIGS. 3A, 3B, sacrificial gates 150 are then formed on the “fin” patterns 101M. The formation of these sacrificial gates 150 is done typically by deposition then lithography/etching. The formation of the sacrificial gates 150 is configured such that the sacrificial gates 150 are mounted on the “fin” patterns 101M, as illustrated in FIG. 3B. The sacrificial gates 150 typically comprise an upper part located on the “fin” pattern 101M, and side parts located on the side flanks of the “fin” pattern 101M. The sacrificial gates 150 typically bear on the substrate S. At this stage, the sacrificial gates 150 are typically surmounted by an etching mask 160, called hard mask, implemented in the structuration of the sacrificial gates 150. The sacrificial gates 150 comprise, for example, in a known manner, an SiO2 thin oxide layer (thickness between 3 nm and 7 nm, for example) and a polycrystalline silicon thick layer. The SiO2 thin oxide layer can form a stop layer during the etching of the polycrystalline silicon of the sacrificial gates 150. The hard mask 160 can be silicon oxide SiO2—, silicon nitride SiN-based, or an SiO2/SiN bilayer.

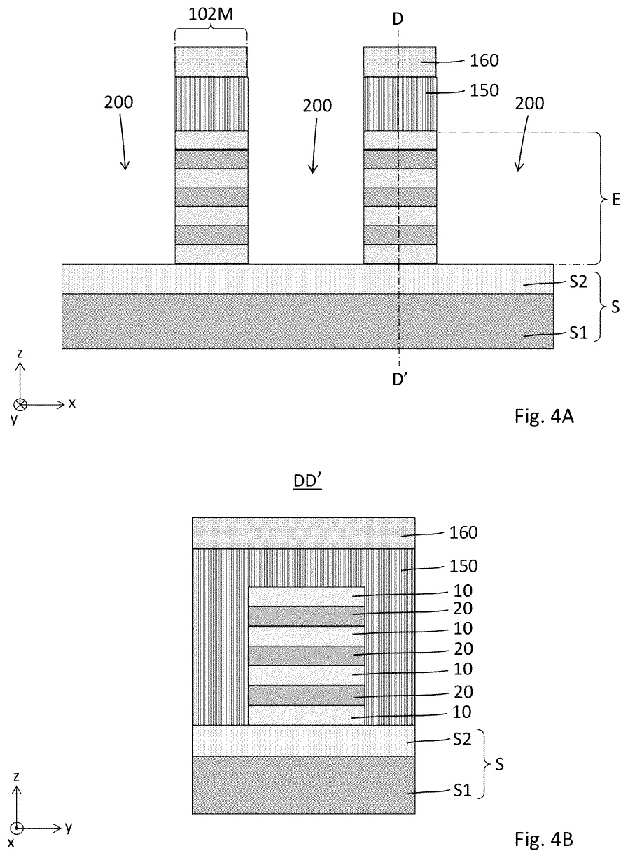

As illustrated in FIGS. 4A, 4B, after formation of the sacrificial gates 150 by lithography/etching, the anisotropic etching along z is extended in order to define second patterns 102M, and second openings 200. The etching is configured to etch the stack E over its entire height, by stopping on the substrate S. It can be done by plasma, by using an HBr/O2 etching chemistry.

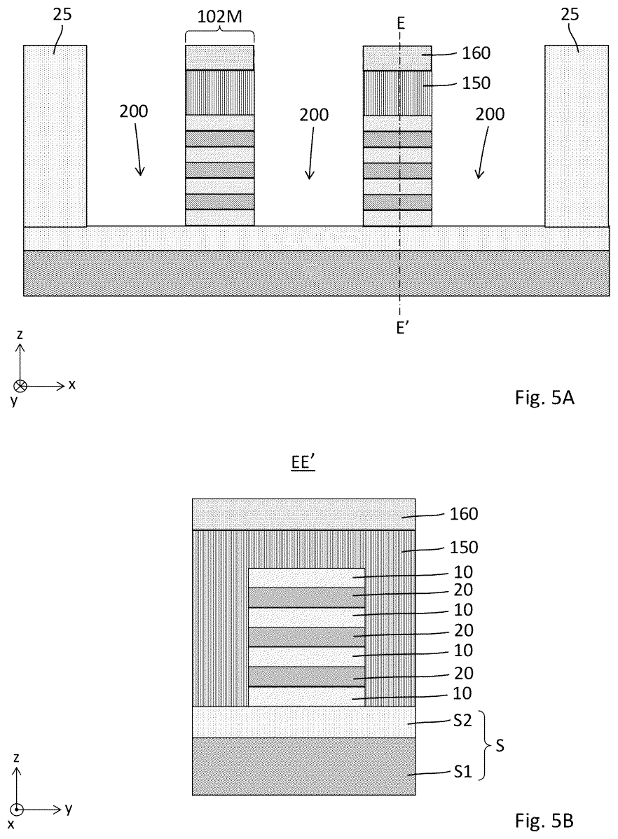

As illustrated in FIGS. 5A, 5B, a dielectric layer 25, for example, SiO2-based, is deposited on and between the second patterns 102M. This dielectric layer 25 is then planarised, typically by chemical-mechanical polishing CMP stopping on the hard masks 160, then opened by etching so as to reform and/or redefine the second openings 200. The second openings 200 are intended to receive the source and drain contacts.

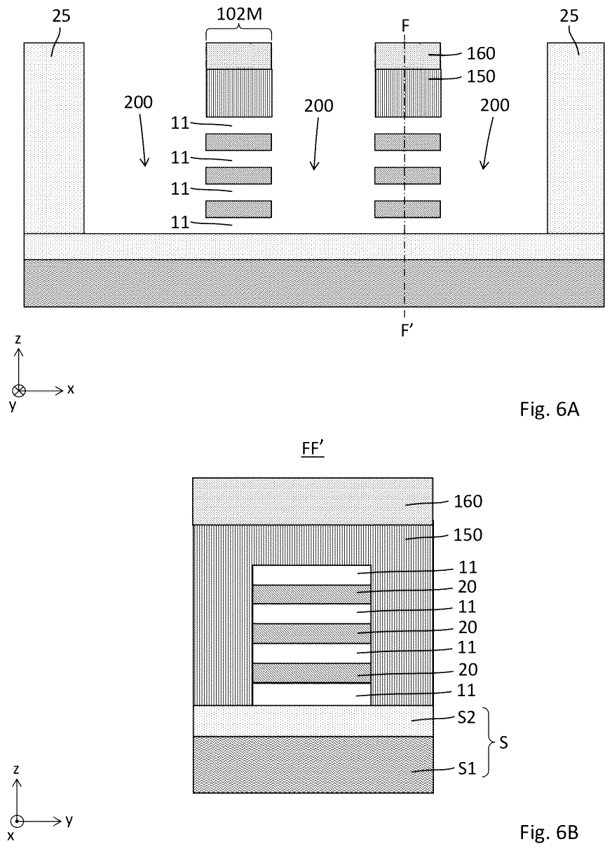

As illustrated in FIGS. 6A, 6B, after formation of the second openings 200, the first layers 10 are totally etched selectively at the second layers 20, at the substrate S and at the sacrificial gates 150. The etching of the first material of the first layers 10 typically has a selectivity S_{10:20} with respect to the second material of the second layers 20, of at least 5:1, preferably at least 10:1. This first etching aims to form first spaces 11 between the second layers 20 of the second patterns 102M. This total etching can be stopped at the time, possibly after an overetching time aiming to guarantee the total removal of the first material from the first layers 10. This total etching has an isotropic character and can be done wet or dry, from the second openings 200.

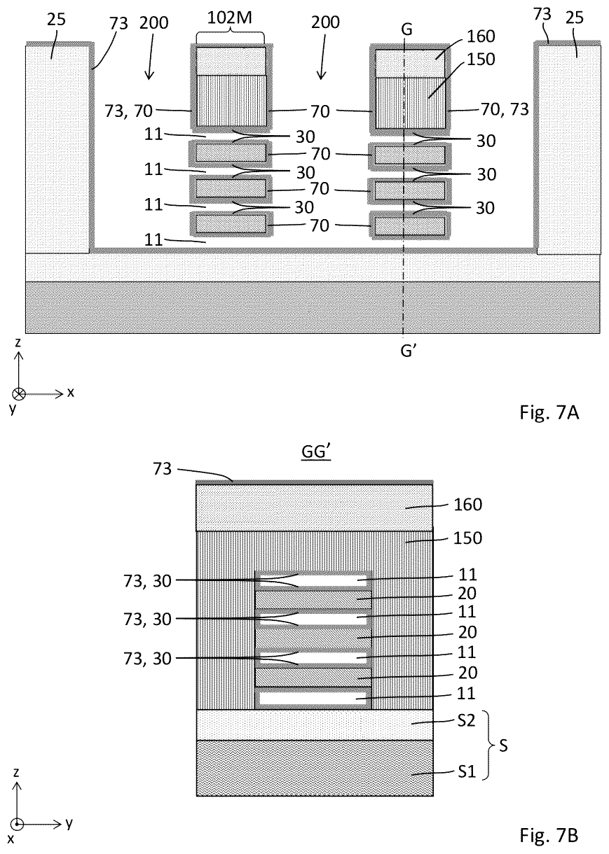

As illustrated in FIGS. 7A, 7B, a continuous layer 73 is then deposited in the second openings 200, around the second layers 20 of the second patterns 102M and around the sacrificial gates 150, in the first spaces 11. The continuous layer 73 typically has a permittivity of between 4 and 25. This continuous layer 73 can thus be with the basis of a high permittivity dielectric material, for example, HfO2-based. The continuous layer 73 is intended to form both the gate dielectric layer 30 between the GAA transistor channels and their gates-all-around, and the spacers 70 on the flanks of the second layers 20 and the sacrificial gates 150. The horizontal portions of the continuous layer 73 typically form the gate dielectric layer 30. The vertical portions of the continuous layer 73 typically form the spacers 70. The continuous layer 73 can be formed by chemical vapour deposition CVD, metal organic chemical vapour deposition MOCVD, or by atomic layer deposition ALD. The continuous layer 73 typically has a thickness of between 1 nm and 5 nm. It can be deposited in a conform manner. It thus has a substantially constant thickness. Alternatively, the deposition can be configured, such that the vertical portions of the continuous layer 73 having a thickness greater than the horizontal portions of the continuous layer 73.

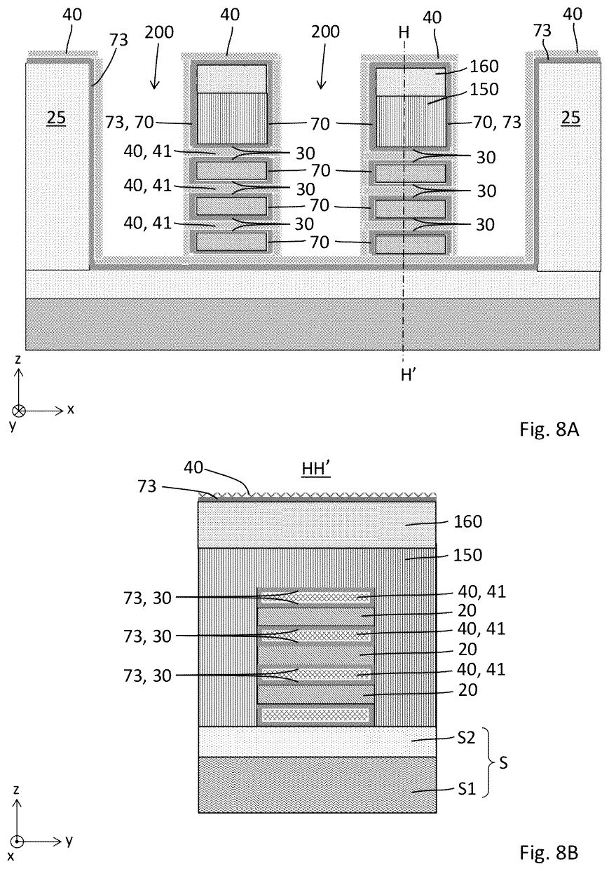

According to an option, several continuous layers 73 are deposited on one another. This makes it possible to adjust the thicknesses of the gate dielectric layer 30 and of the spacers 70. This makes it possible to adjust the dielectric properties of the gate dielectric layer 30 and of the spacers 70. As illustrated in FIGS. 8A, 8B, a layer 40 with the basis of a semiconductive material is then deposited on the continuous layer 73 in the first spaces 11. The deposition of the semiconductive material is, in this case, configured such that the layer 40 totally fills the first spaces 11. The portions of the layer 40 located in the first spaces 11 thus have a fully controlled thickness, close to the thickness of the first initial layers. This layer 40 is intended to form the channels 41 of the GAA transistors in vertical alignment with the sacrificial gates 150 and with the second layers 20. This layer 40 is also intended to form the sources 42 and the drains 43 of the GAA transistors in vertical alignment with the spacers 70.

The layer 40 is also typically deposited outside of the first spaces 11, on (some or all) of the flanks of the spacers 70. This makes it possible to improve the reconnection with the sources 42 and the drains 43 of the GAA transistors. The layer 40 thus has horizontal portions in the first spaces 11, in particular, between the second layers, and vertical portions on the flanks of the spacers 70, without discontinuity. According to an option, the thickness of the vertical portions of the layer 40 is greater than the thickness of the horizontal portions of the layer 40. This makes it possible to reduce the contact resistance for the sources 42 and the drains 43 of the GAA transistors.

The semiconductive material of the layer 40 is advantageously a two-dimensional material taken from among MX2 transition metal dichalcogenides, with M, molybdenum (Mo) or tungsten (W), and X, sulphur(S), selenium (Se) or tellurium (Te). Such a 2D material can be advantageously deposited in the form of a thin layer comprising 1 to 10 atomic layers, preferably 1 to 5 atomic layers. The deposition of this 2D material can be done by CVD, MOCVD or ALD. According to another option, the semiconductive material of the layer 40 is a semiconductive oxide, such as ITO (indium tin oxide), IGZO (indium gallium zinc oxide), IWO (“tungsten-doped indium oxide”), indium oxide In2O3. According to another option, the semiconductive material of the layer 40 is a graphene, a hexagonal boron nitride “h-BN”, a phosphorene (also called “Black Phosphorous” BP), in the form of a monolayer or a thin layer comprising 1 to 10 atomic layers, preferably 1 to 5 atomic layers.

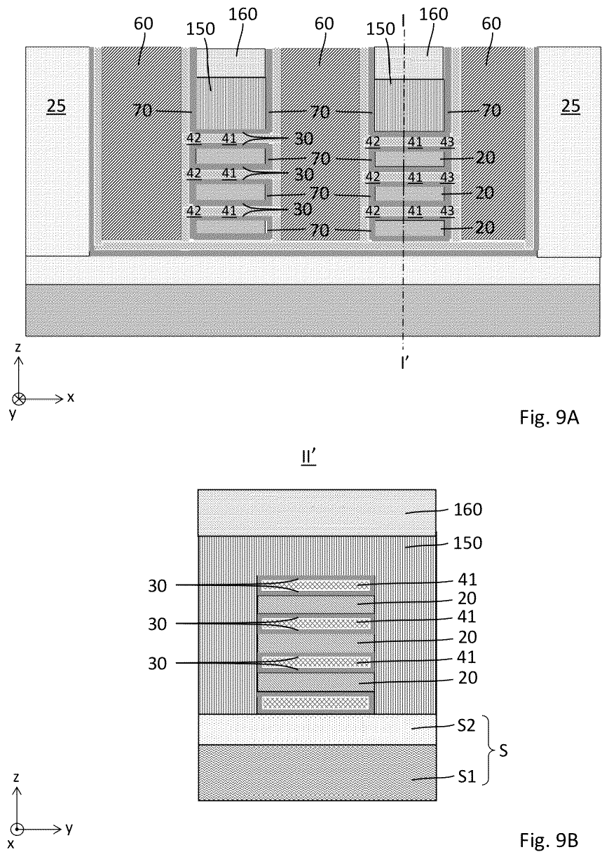

As illustrated in FIGS. 9A, 9B, the second openings can then be filled with one or more metal layers 60, for example, Ti-, TiN-, W-based, in order to form the source and drain contacts. A chemical-mechanical polishing CMP is typically done in order to remove the excess metal deposited on the patterns 102M. The hard masks 160 are thus exposed.

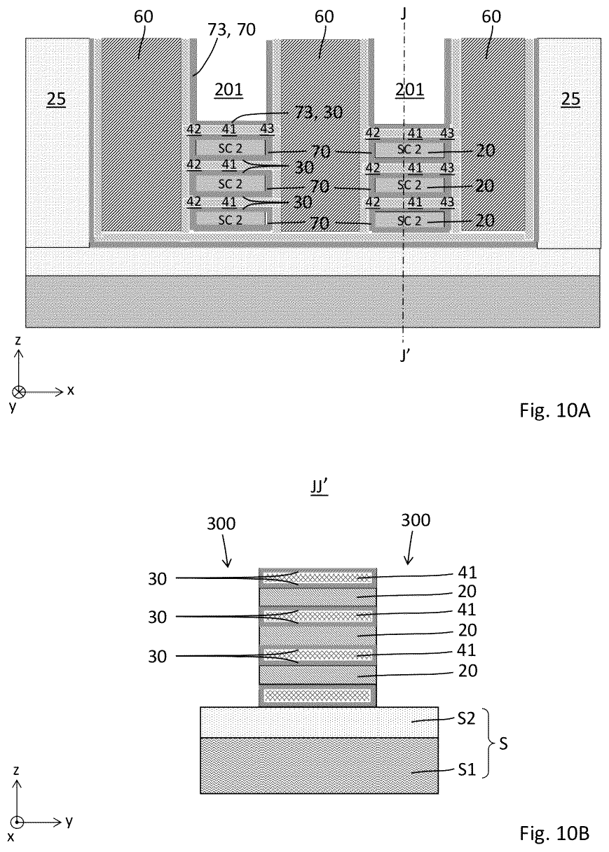

As illustrated in FIGS. 10A, 10B, the hard masks 160 are first removed, then the sacrificial gates 150 are also removed. One or more oxide stoppers can be made on the source and drain contacts before these removals, to protect the metal layers 60 during the removal of the hard masks 160 and of the sacrificial gates 150. This removal can be done by wet etching stopping on the continuous layer 73. This wet etching typically has a high selectivity with respect to the continuous layer 73. This wet etching can be with the basis of a TMAH (tetramethylammonium hydroxide) or TEAH (tetraethylammonium hydroxide) salt solution. The removal of the sacrificial gates 150 is typically done in two steps, with a first etching of polycrystalline silicon and stopping on the SiO2 thin oxide layer, then a second etching of this SiO2 thin oxide layer. The removal of the sacrificial gates 150 makes it possible to form a main space 201 and third openings 300 opening onto the second layers 20 (FIG. 10B).

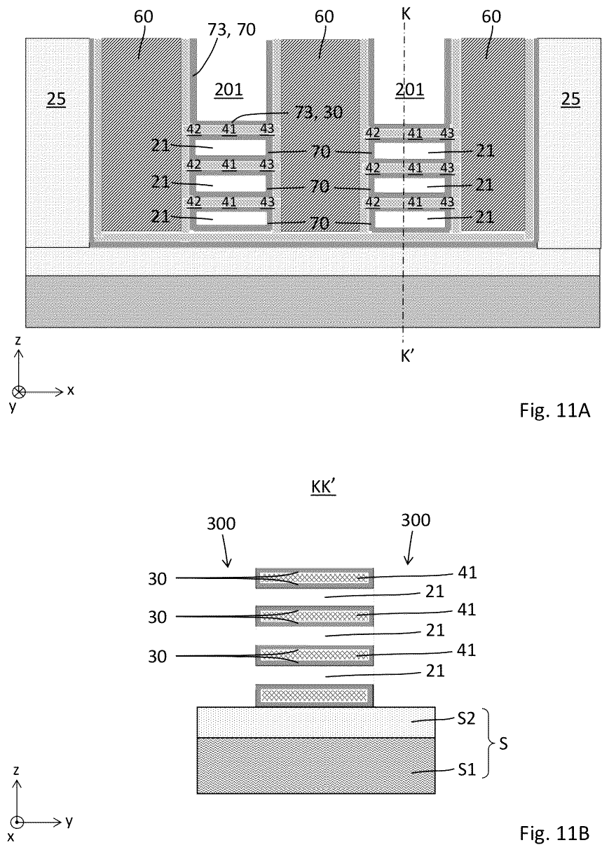

As illustrated in FIGS. 11A, 11B, the second layers 20 are then totally removed by selective etching with respect to the continuous layer 73, from the third openings 300. This etching aims to form second spaces 21 instead of the second layers 20. This etching has an isotropic character and can be done wet or dry, from the third openings 300.

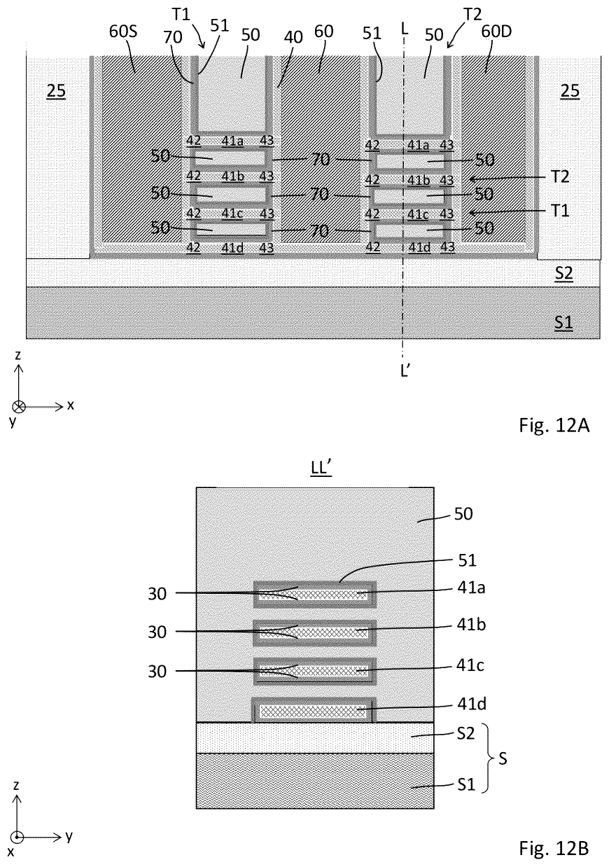

As illustrated in FIGS. 12A, 12B, the main spaces 201 and the second spaces 21 are then filled with one or more metal layers 50, for example, TiN-, W-based, in order to form the gates-all-around of the GAA transistors. According to an option, before deposition of the metal layers 50, a dielectric layer 51 with the basis of a high permittivity material, for example, HfO2-based, is deposited beforehand in the main spaces 201 and the second spaces 21. This makes it possible to increase the thickness of the gate dielectric layer between the channels 41 of the GAA transistors and their gates-all-around 50. This makes it possible to increase the thickness of the spacers between the gates-all-around 50 and the sources and drains of the GAA transistors. A chemical-mechanical polishing CMP is typically done in order to remove the excess metal deposited on the patterns 102M.

A microelectronic device comprising two transistors T1, T2, each comprising four channels 41a, 41b, 41c, 41d stacked along z, with a gate-all-around 50, is thus advantageously obtained. The channels 41a, 41b, 41c, 41d, the sources 42 and the drains 43 are preferably with the basis of a two-dimensional material. Source and drain contacts 60S, 60, 60D electrically connect these transistors GAA T1, T2.

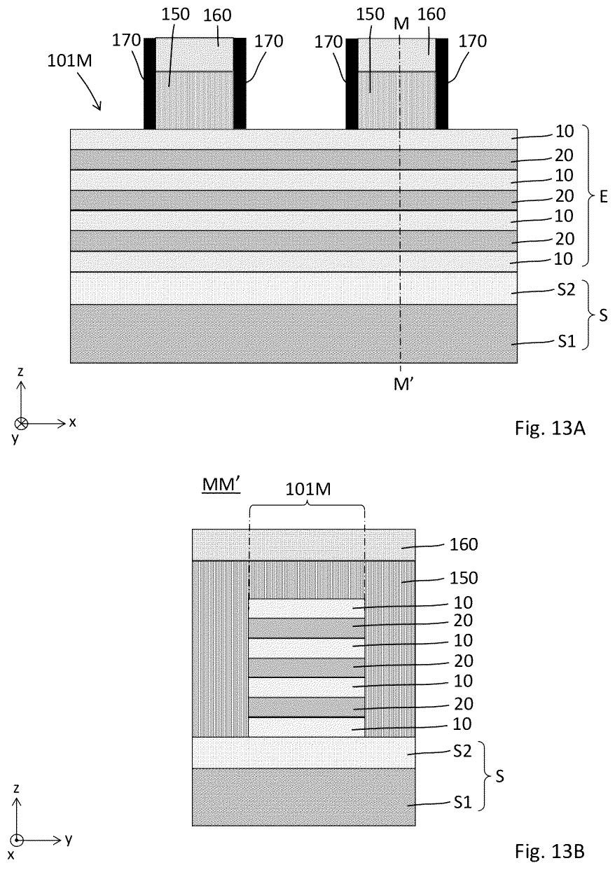

FIGS. 13A, 13B to 20A, 20B schematically illustrate steps of manufacturing a device comprising GAA transistors according to a second embodiment. Figures nA (n=13 . . . 20) correspond to first transverse cross-sections, each illustrating a different step of the manufacturing method. Figures nB (n=13 . . . 20) correspond to second transverse cross-sections, each illustrating the same step as corresponding figure nA.

Only the different features of this second embodiment with respect to the first embodiment are described below. Other features are considered identical to those of the first embodiment, in reference to the above.

As illustrated in FIGS. 13A, 13B, after formation of the first patterns 101M and of the sacrificial gates 150 mounted on these patterns 101M, additional spacers 170 are formed on the flanks oriented along yz of the sacrificial gates 150. Generally, projecting along z, these spacers form a continuous ring around each sacrificial gate 150, with a closed contour.

In a transverse cross-section, however, along the plane xz illustrated in FIG. 13A, the thickness 170 has two parts opposite one another on each of the flanks of the sacrificial gate 150. These two parts are generally referenced as being the spacers 170, even if these can be considered as belonging to one single and same spacer. The spacers 170 typically extend to an upper face of the hard masks 160. The spacers 170 are typically silicon nitride SiN-based, or made of a dielectric material with a low dielectric constant. The spacers 170 typically have a thickness along x of between 2 nm and 7 nm. These spacers 170 can be formed by a deposition and an anisotropic etching along z.

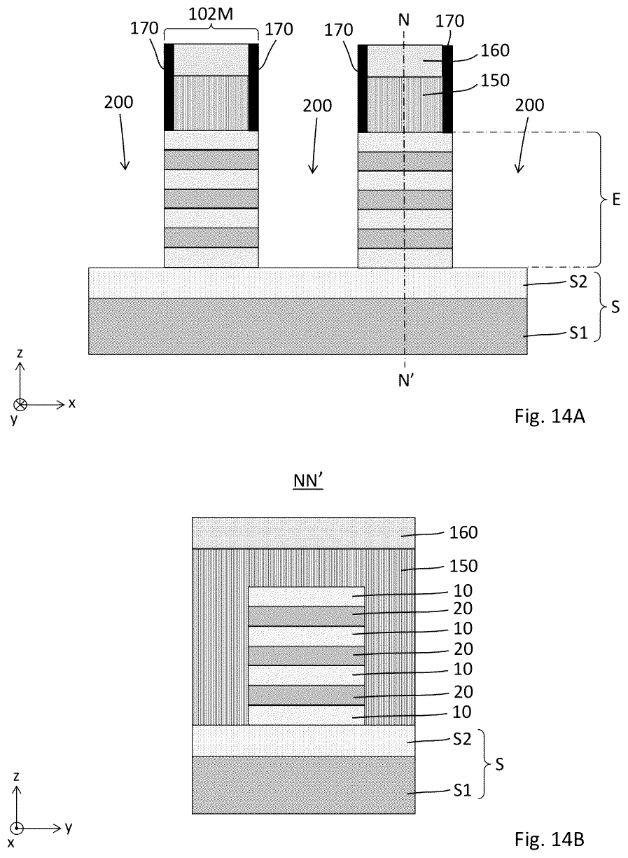

As illustrated in FIGS. 14A, 14B, after formation of the additional spacers 170, the anisotropic etching along z is extended in order to define the second patterns 102M, and the second openings 200, as above.

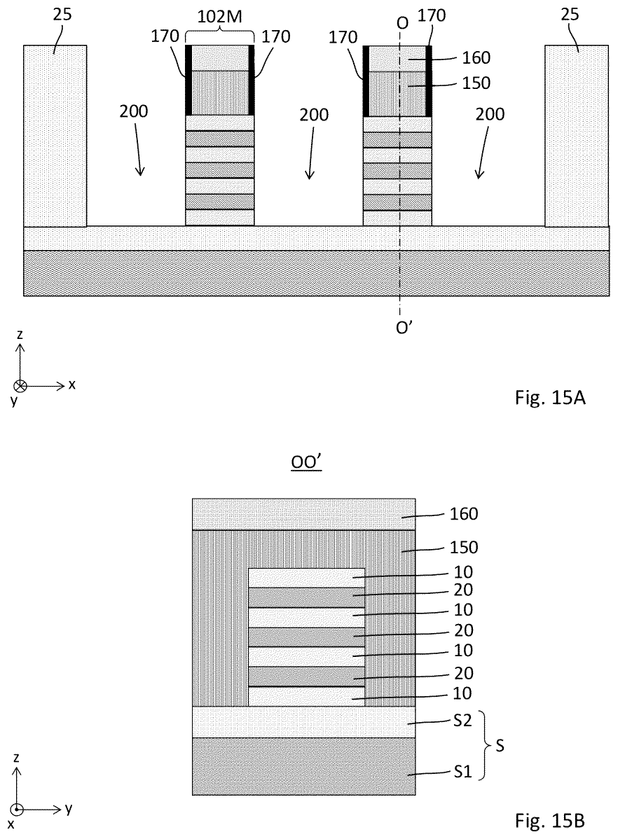

As illustrated in FIGS. 15A, 15B, a dielectric layer 25, for example, SiO2-based, is deposited on and between the second patterns 102M, the planarised and opened, as above.

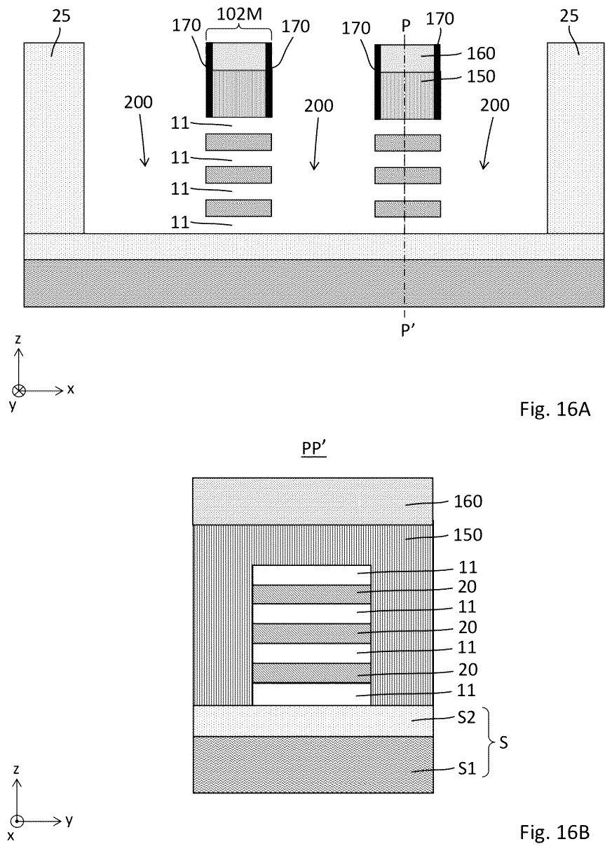

As illustrated in FIGS. 16A, 16B, after formation of the second openings 200, the first layers 10 are totally etched selectively at the second layers 20 to form the first spaces 11, as above.

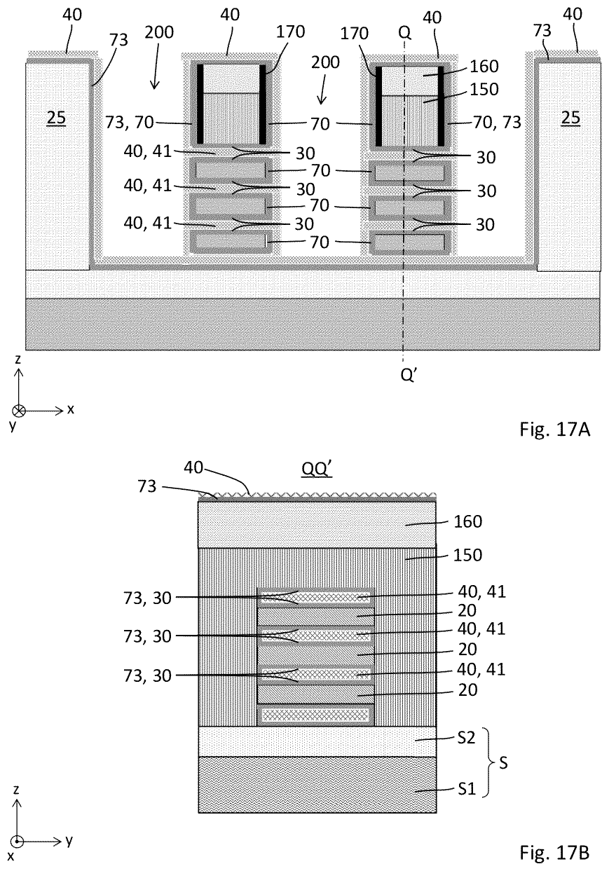

As illustrated in FIGS. 17A, 17B, a continuous layer 73 is then deposited in the second openings 200, around the second layers 20 of the second patterns 102M and on the additional spacers 170, in the first spaces 11. This continuous layer 73 is formed as above. A layer 40 with the basis of the semiconductive material is then deposited on the continuous layer 73 in the first spaces 11 and on the vertical portions of the continuous layer 73. This layer 40 is formed as above.

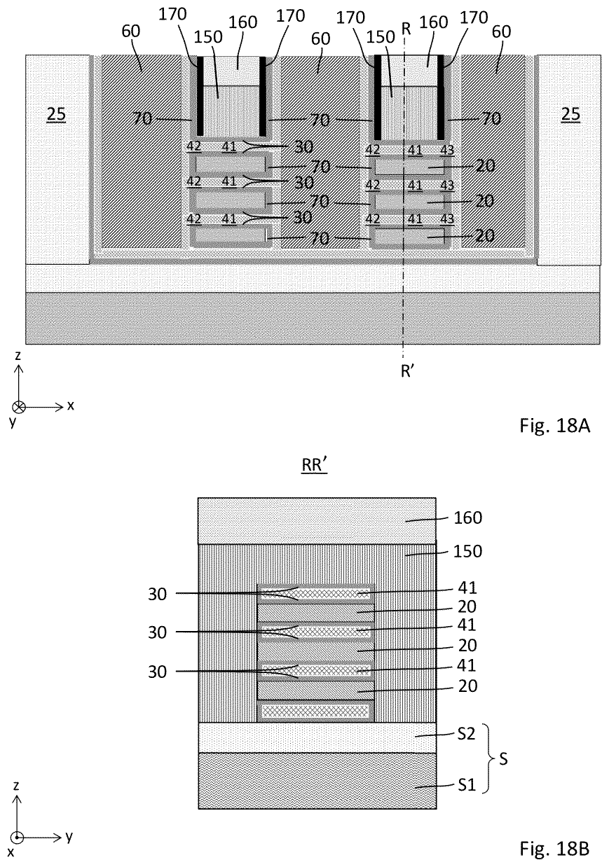

As illustrated in FIGS. 18A, 18B, the second openings are then filled with one or more metal layers 60 to form the source and drain contacts, as above.

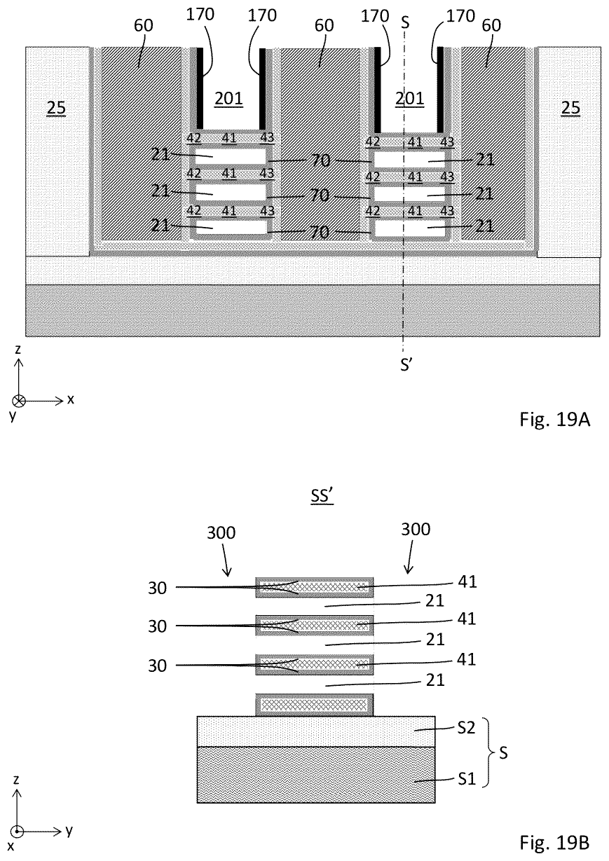

As illustrated in FIGS. 19A, 19B, the hard masks 160 are removed, then the sacrificial gates 150 are also removed. This removal can be done by wet etching, stopping on the continuous layer 73 and on the spacers 170. This wet etching typically has a high selectivity with respect to the continuous layer 73 and the spacers 170. This wet etching can be with the basis of a TMAH (tetramethylammonium hydroxide) or TEAH (tetraethylammonium hydroxide) salt solution. The second layers 20 are then totally removed by selective etching with respect to the continuous layer 73, from the third openings 300. A main space 201 and second spaces 21 are thus formed, as above.

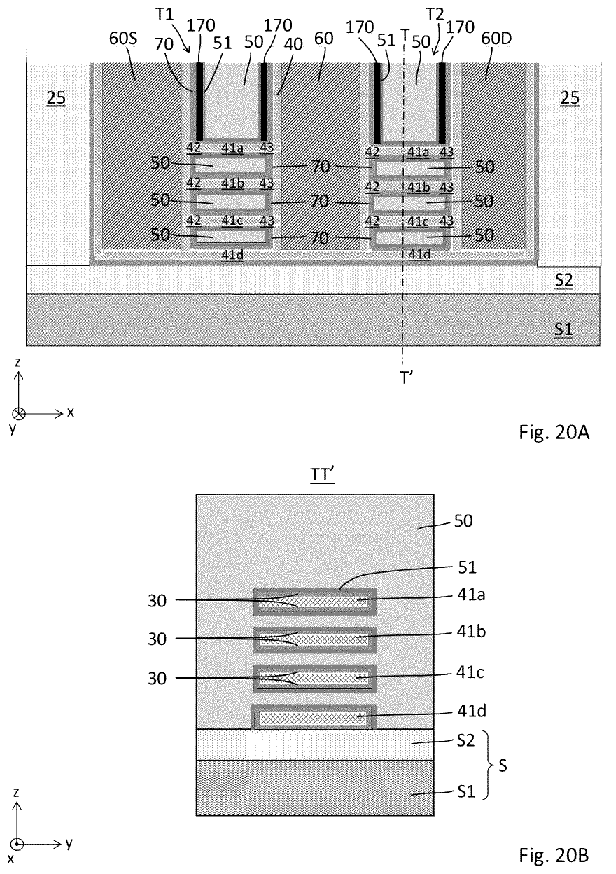

As illustrated in FIGS. 20A, 20B, the gates-all-around 50 are then formed in the main spaces 201 and the second spaces 21, as above. A dielectric layer 51 can be deposited beforehand in the main spaces 201 and the second spaces 21, as above. A microelectronic device comprising two transistors T1, T2, each comprising four channels 41a, 41b, 41c, 41d stacked along z, with a gate-all-around 50, is thus advantageously obtained. The channels 41a, 41b, 41c are totally coated by the gate-all-around 50. The channel 41d is partially coated by the gate-all-around 50. The channels 41a, 41b, 41c, 41d, the sources 42 and the drains 43 are preferably with the basis of a two-dimensional material. Source and drain contacts 60S, 60, 60D electrically connect these channels 41a, 41b, 41c, 41d stacked along z. Advantageously, the additional spacers 170 of this second embodiment make it possible to reduce the interfering capacities of the device.

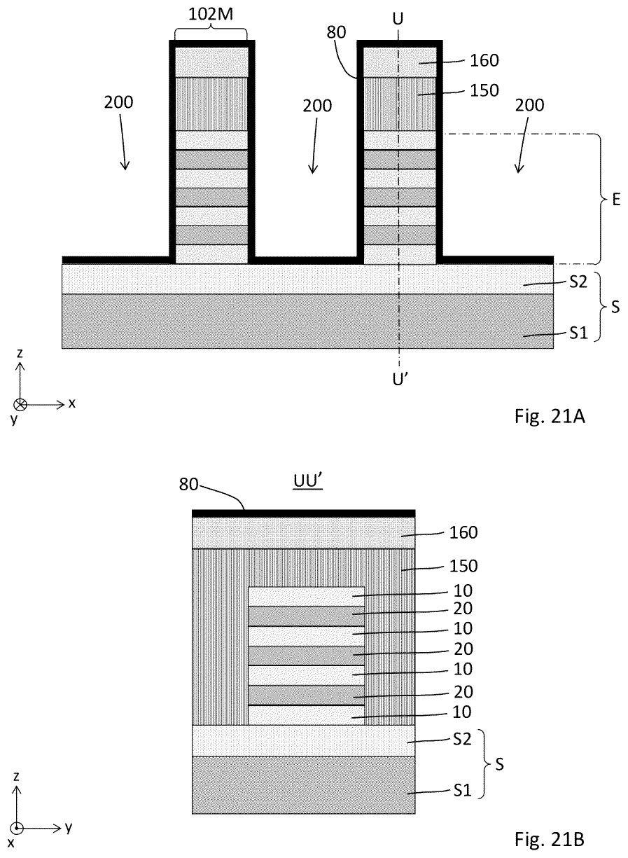

The first and second embodiments are of the “gate last” type. FIGS. 21A, 21B to 31A, 31B schematically illustrate steps of manufacturing a device comprising GAA transistors according to a third embodiment of the “gate first” type. Figures nA (n=21 . . . 31) correspond to first transverse cross-sections, each illustrating a different step of the manufacturing method. Figures nB (n=21 . . . 31) correspond to second transverse cross-sections, each illustrating the same step as corresponding figure nA.

Only the different features of this third embodiment regarding first and second embodiments are described below. The other features are considered identical to those of the first and/or of the second embodiment, in reference to the above.

As illustrated in FIGS. 21A, 21B, after formation of second patterns 102M and of the second openings 200 as in the first embodiment, a holding layer or liner 80 is deposited on said patterns 102M and in the second openings 200. This holding layer 80 is, for example, SiN-based. It typically has a thickness of between 3 nm and 7 nm.

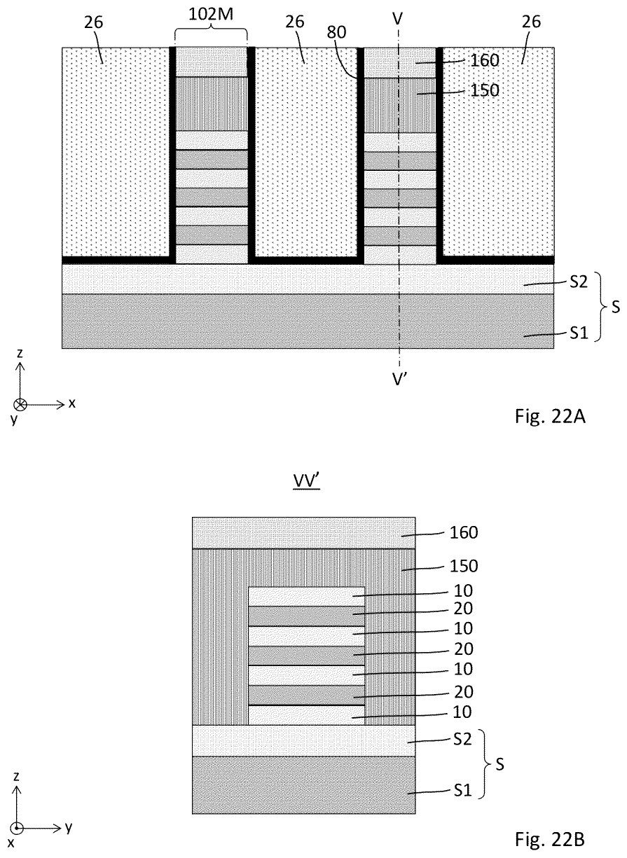

As illustrated in FIGS. 22A, 22B, a dielectric layer, for example, SiO2-based, is deposited on the holding layer 80. It typically has a large thickness, for example, around 600 nm. This dielectric layer 26 is then planarised, typically by chemical-mechanical polishing CMP stopping on the hard masks 160.

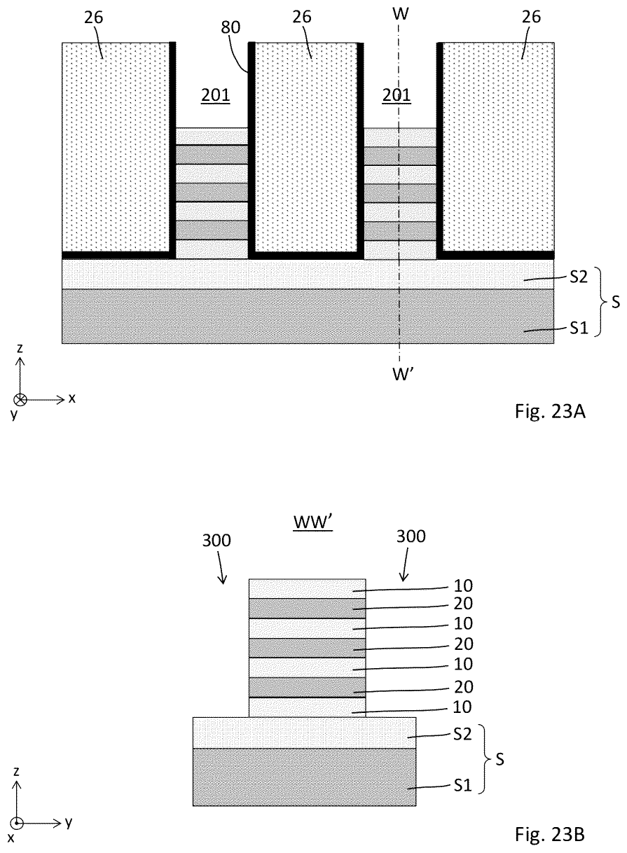

As illustrated FIGS. 23A, 23B, at this stage, the hard masks 160 are removed, then the sacrificial gates 150 are also removed. This removal can be done by wet etching stopping on the holding layer 80 and on the first material of the first layers 10. This wet etching typically has a high selectivity with respect to the holding layer 80 and of the first material. This wet etching can be with the basis of a TMAH (tetramethylammonium hydroxide) or TEAH (tetraethylammonium hydroxide) ammoniac salt solution. This removal of the sacrificial gates 150 makes it possible to form a main space 201 and third openings 300 opening, in particular, onto the second layers 20 (FIG. 23B).

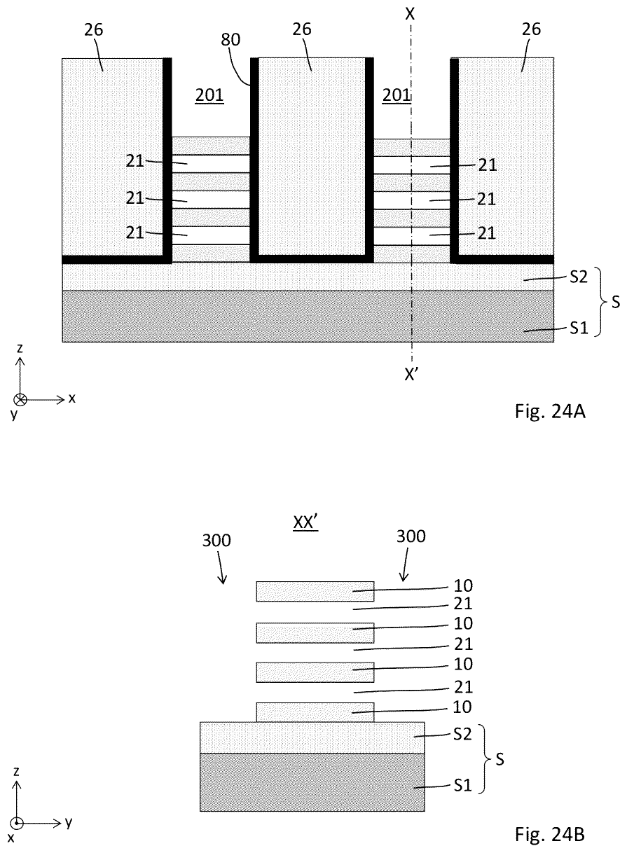

As illustrated in FIGS. 24A, 24B, the second layers 20 are then totally removed by selective etching with respect to the first material of the first layers 10, from the third openings 300. A main space 201 and second spaces 21 are thus formed, as above.

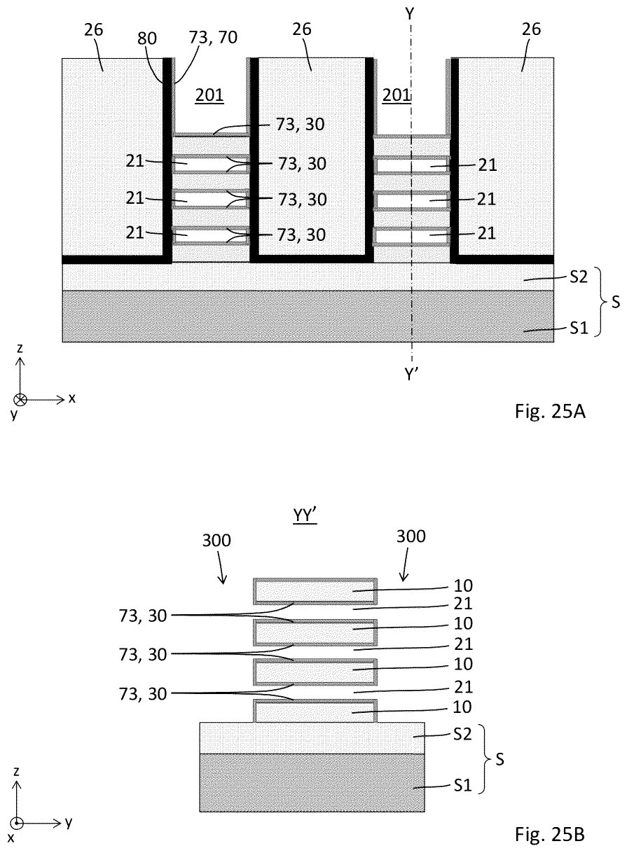

As illustrated in FIGS. 25A, 25B, a continuous layer 73 is then deposited in the main space 201 and in the second spaces 21, from the third openings 300. This continuous layer 73 is formed as above. It is intended to form both the gate dielectric layer 30 between the GAA transistor channels and their gates-all-around, and the spacers 70. The horizontal portions of the continuous layer 73 typically form the gate dielectric layer 30. The vertical portions of the continuous layer 73 typically form the spacers 70. The spacers 70, in this case, bear on the holding layer 80.

According to an option, several continuous layers 73, for example, SiO2 and/or HfO2 and/or Al2O3-based, are deposited on one another. This makes it possible to adjust the thicknesses of the gate dielectric layer 30 and of the spacers 70. This makes it possible to adjust the dielectric properties of the gate dielectric layer 30 and of the spacers 70.

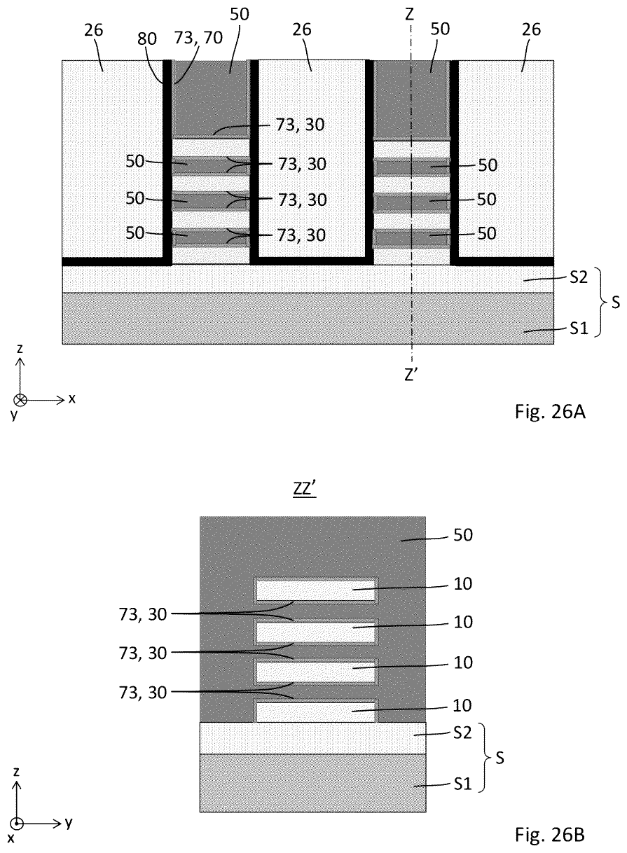

As illustrated in FIGS. 26A, 26B, the main spaces 201 and the second spaces 21 are then filled with one or more metal layers 50, for example, TiN-, W-based, in order to form the gates-all-around of the GAA transistors.

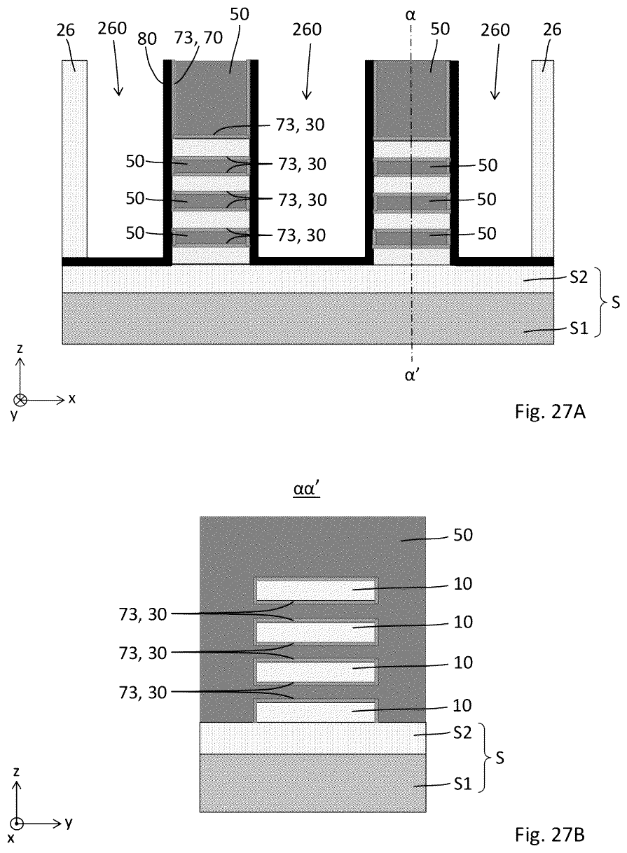

As illustrated in FIGS. 27A, 27B, the layer 26 is opened by etching, so as to form openings 260. This etching typically stops on the liner 80. One or more nitride-based stoppers can be made on the gates 50 before etching the layer 26, to protect the metal layers 50 before etching the layer 26, to protect the metal layers 50 during the etching of this layer 26.

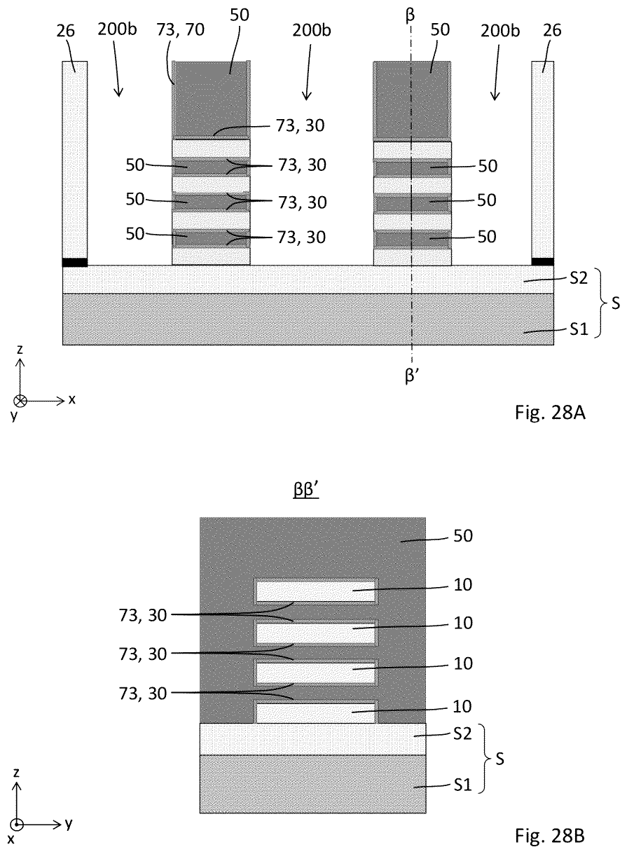

As illustrated in FIGS. 28A, 28B, the liner 80 exposed in the openings 260 is removed, selectively at the continuous layer 73 and at the first material of the first layers 10. This removal can be done by wet etching or by isotropic dry etching. This wet etching can be with the basis of a H3P04 phosphoric acid solution concentrated at 50%, done at 100° C. for a few tens of minutes, for example, 30 minutes. The second openings 200b are thus reformed. The second openings 200b are intended to receive the source and drain contacts. They open onto the first layers 10.

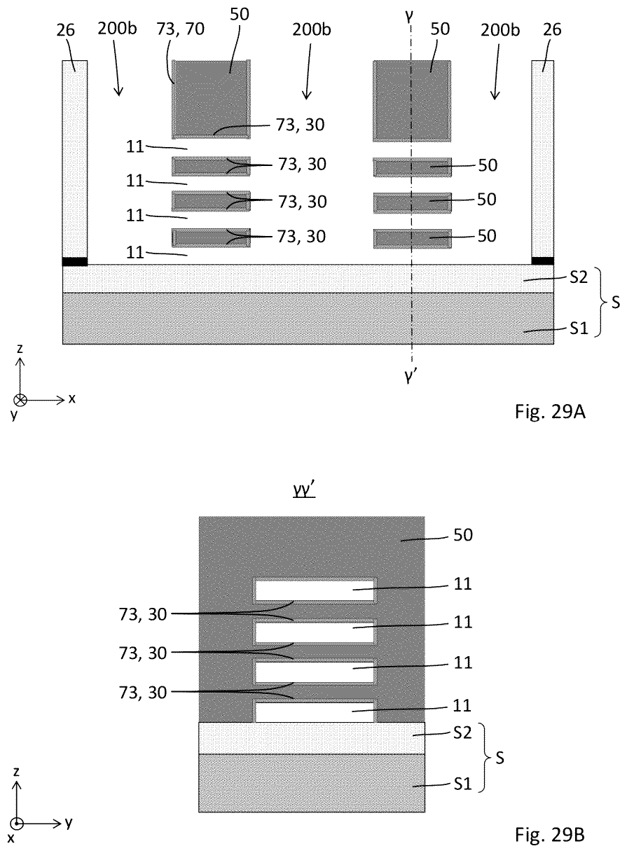

As illustrated in FIGS. 29A, 29B, the first layers 10 are then totally removed by selective etching with respect to the continuous layer 73, from the second openings 200b. This etching aims to form first spaces 11 instead of the first layers 10. This etching has an isotropic character and can be done wet or dry, from the second openings 200b.

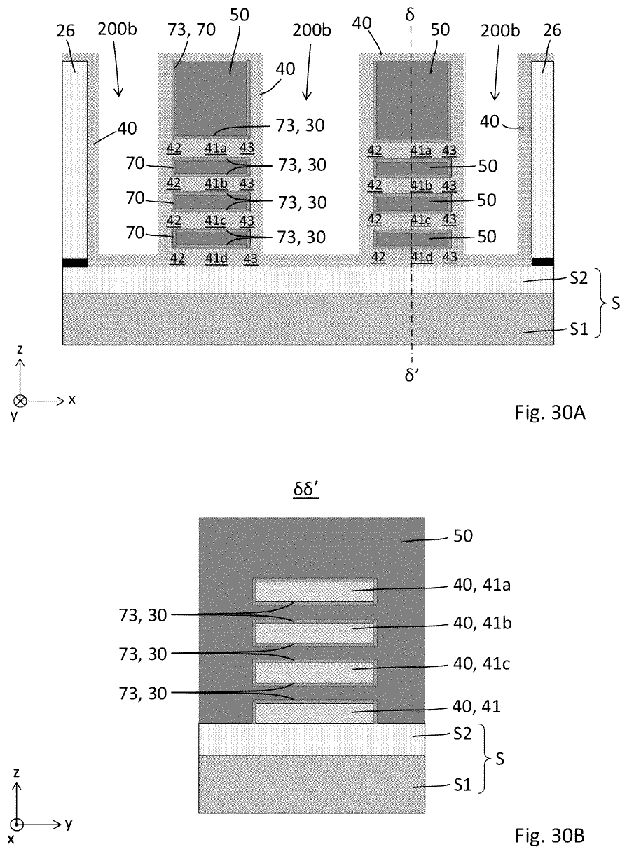

As illustrated in FIGS. 30A, 30B, the layer 40 with the basis of the semiconductive material is then deposited on the continuous layer 73 in the first spaces 11. The deposition of the semiconductive material is, in this case, configured such that the layer 40 totally fills the first spaces 11. The portions of the layer 40 located in the first spaces 11 thus have a fully controlled thickness, around equal to the thickness of the first initial layers. This layer 40 is intended to form the GAA transistor channels 41 in vertical alignment of the sacrificial gates 150 and of the second layers 20. This layer 40 is also intended to form the sources 42 and the drains 43 of the GAA transistors in vertical alignment with the spacers 70, and preferably, on the vertical flanks of the spacers 70.

The layer 40 is also typically deposited outside of the first spaces 11, on some or all of the flanks of the spacers 70. This makes it possible to improve the reconnection with the sources 42 and the drains 43 of the GAA transistors. The semiconductive material of the layer 40 is advantageously a 2D material, as above.

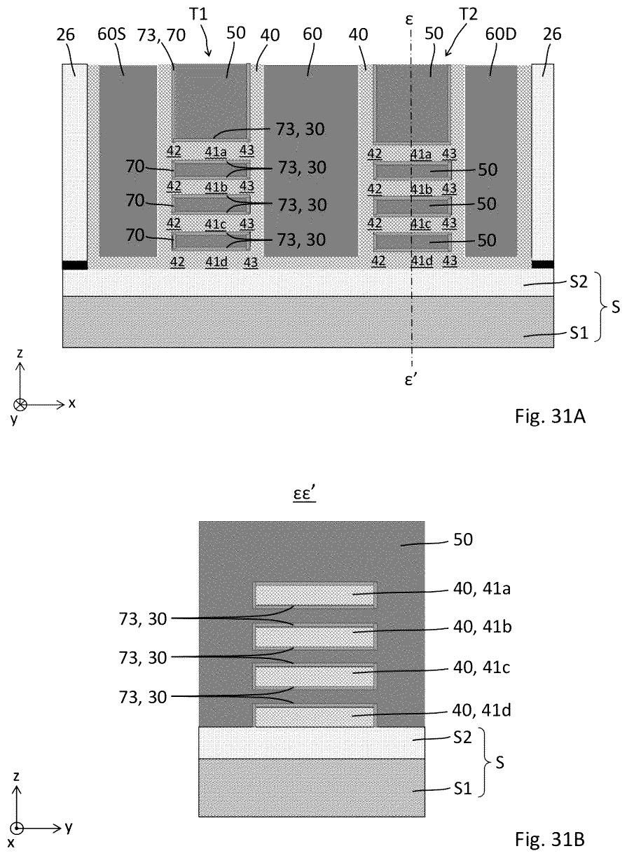

As illustrated in FIGS. 31A, 31B, the second openings 200b can then be filled with one or more metal layers 60, for example, Ti-, TiN-, W-based, in order to form the source and drain contacts. A chemical-mechanical polishing CMP is typically done in order to remove the excess metal deposited on the patterns 102M. The tops of the gates 50 are thus exposed.

A microelectronic device comprising two transistors T1, T2, each comprising four channels 41a, 41b, 41c, 41d stacked along z, with a gate-all-around 50 or partially coated gate, is thus advantageously obtained. The channels 41a, 41b, 41c, 41d, the sources 42 and the drains 43 are preferably with the basis of a two-dimensional material. Source and drain contacts 60S, 60, 60D electrically connect the channels 41a, 41b, 41c, 41d of these GAA transistors T1, T2.

In view of the description above, it clearly appears that the proposed method offers a particularly effective solution for forming 2D material-based GAA transistors. This solution is further advantageously compatible with standard microelectronic methods. The invention is however not limited to the embodiments described above.

According to an option not illustrated, the layer 40 with the basis of the semiconductive material does not totally fill the first spaces 11. In this case, the portions of the layer 40 located in the first spaces 11 can be significantly thinner that the first initial layers. These horizontal portions can have a thickness corresponding to a few atomic layers only, for example, between 1 and 5 atomic layers of semiconductive material. This makes it possible to reduce the dimensions of the GAA transistor channels 41. The performance of GAA transistors can be improved. A dielectric stopper is typically formed between the horizontal portions of the layer 40, in order to fill the first spaces 11. This makes it possible to work with one single 2D material monolayer, which makes it possible to obtain an excellent electrostatic control of the device. The gate length can thus be advantageously reduced. This also makes it possible to improve the mechanical resistance of the device and/or avoid deformations of the GAA transistor channels, for example, by heating during operation. This dielectric stopper can be formed by CVD deposition and etching, conventionally.

Other embodiments can be considered. The additional spacers of the second embodiment can, for example, be added in the scope of the third embodiment, to form another embodiment. The compatible features of the different embodiments can be combined with one another to form an embodiment which is not necessarily illustrated or described.

1. A microelectric device comprising at least one transistor, the device comprising:
at least two channels stacked along a main direction each channel being with a basis of a semiconductive material,
a gate-all-around, totally surrounding at least one of the channels,
a source and a drain on either side of each channel, and source and drain contacts connected respectively to the source and to the drain,
a gate dielectric layer separating each channel and the gate-all-around,
spacers on either side of the gate, and configured to electrically isolate the gate with respect to the source and drain contacts,
wherein the gate dielectric layer and the spacers are formed by one same continuous layer surrounding the gate-all-around, and in that each channel, source, and drain are formed by one same layer with the basis of the semiconductive material, said layer totally surrounding the continuous layer and having vertical portions on the flanks of the spacers and horizontal portions on each gate dielectric layer.

2. The device according to claim 1, wherein said continuous layer has horizontal parts, extending into a plane perpendicular to the main direction and vertical parts, extending planes parallel to the main direction, and wherein the gate dielectric layer corresponds to the horizontal parts of the continuous layer, and the spacers correspond to the vertical parts of the continuous layer.

3. The device according to claim 1, wherein the source and the drain are common to all the channels of the at least one transistor.

4. The device according to claim 1, wherein the semiconductive material of the channels is taken from among:
MX2 transition metal dichalcogenides, with M taken from among molybdenum or tungsten, and X taken from among sulphur, selenium, or tellurium, or
a semiconductive oxide, being one of IGZO (indium gallium zinc oxide), In2O3, IWO (tungsten-doped indium oxide), ITO (indium tin oxide), IAZO (indium aluminium zinc oxide), InGaZnO, InGaO, InZnO, or an amorphous semiconductive oxide, or
graphene, hexagonal boron nitride, or phosphorene.

5. The device according to claim 1, wherein the continuous layer has a thickness of between 1 nm and 5 nm.

6. The method for manufacturing a microelectronic device according to claim 1, said method comprising the:
providing, on a substrate, a stack along the main direction comprising a first plurality of first layers made of a first material alternated with a second plurality of second layers made of a second material, the first and second materials being different from said semiconductive material,
forming, in this stack, first openings defining first patterns,
forming sacrificial gates mounted on the first patterns and partially in the first openings,
forming, in the first patterns, second openings defining second patterns,
totally removing, from the second openings, the first material of the first layers, so as to form first spaces,
removing the sacrificial gates, so as to form third openings,
totally removing, from the third openings, the second material of the second layers, so as to form second spaces,
depositing a continuous layer, with a basis of a dielectric material, around second layers or in the second spaces, so as to form:
a gate dielectric layer from the horizontal parts of the continuous layer, and
spacers from the vertical parts of the continuous layer,
after formation of the continuous layer, depositing a layer with the basis of a semiconductive material in the first spaces, so as to form:
channels with the basis of the semiconductive material, and
sources and drains with the basis of the semiconductive material on either side of the channels,
after formation of the continuous layer, filling with a gate material, the second spaces, so as to form gates-all-around totally surrounding at least one of the channels of the at least one transistor.

7. The method according to claim 6, wherein the removal of the sacrificial gates and the removal of the second material from the second layers are performed after deposition of the layer with the basis of the semiconductive material, and wherein the deposition of the continuous layer is done around second layers.

8. The method according to claim 7, wherein the removal of the first material from the first layers is performed selectively at the second material of the second layers.

9. The method for manufacturing a microelectronic device according to claim 6, said method comprising the steps below, sequenced in the following order:
providing, on a substrate, the stack along the main direction comprising the first plurality of first layer made of a first material alternated with the second plurality of second layers made of a second material, the first and second materials being different from the semiconductive material,
forming, in this stack, the first openings defining the first patterns,
forming the sacrificial gates mounted on the first patterns and partially in the first openings,
forming in the first patterns, the second openings defining the second patterns,
totally removing, from the second openings, the first material from the first layers, so as to form the first spaces,
depositing the continuous layer, with the basis of a dielectric material, around the second layers, so as to form:
the gate dielectric layer from the horizontal parts of the continuous layer, and
the spacers from the vertical parts of the continuous layer,
depositing the layer with the basis of a semiconductive material on the continuous layer, in the first spaces, so as to form:
channels with the basis of the semiconductive material, and
sources and drains with the basis of the semiconductive material on either side of the channels,
removing the sacrificial gates, so as to form the third openings,
totally removing, from the third openings, the second material from the second layers, so as to form the second spaces, and
filling the second spaces with the gate material, so as to form the gates-all-around, totally surrounding at least one channel of the at least one transistor.

10. The method according to claim 6, wherein the removal of the sacrificial gates and the removal of the second material from the second layers are performed before deposition of the layer with the basis of the semiconductive material, and wherein the deposition of the at least one continuous layer is done in the second spaces.

11. The method according to claim 10, further comprising, after formation of the second openings, a deposition of at least one holding layer in said second openings, on exposed flanks of the first and second layers.

12. The method according to claim 11, further comprising, after filling of the second spaces with the gate material, a removal of the at least one holding layer, so as to expose the flanks of the first layers.

13. The method for manufacturing a microelectronic device according to claim 12, said method comprising the steps below, sequenced in the following order:
providing, on a substrate, the stack along the main direction comprising the first plurality of first layers made of a first material alternated with the second plurality of second layers made of a second material, the first and second materials being different from the semiconductive material,
forming, in this the stack, the first openings defining the first patterns,
forming the sacrificial gates mounted on the first patterns and partially in the first openings,
forming, in the first patterns, the second openings defining the second patterns,
forming the holding layer in said second openings, on exposed flanks of the first and second layers,
removing the sacrificial gates, so as to form the third openings,
totally removing, from the third openings, the second material of the second layers, so as to form the second spaces,
depositing the continuous layer, with the a basis of a dielectric material, in the second spaces, so as to form:
the gate dielectric layer from the horizontal parts of the continuous layer, and
the spacers from the vertical parts of the continuous layer,
filling the second spaces with the gate material, so as to form the gates-all-around,
removing the holding layer, so as to expose the flanks of the first layers,
totally removing, from the second openings, the first material of the first layers, so as to form the first spaces, and
depositing the layer with the basis of a semiconductive material on the continuous layer, in the first spaces, so as to form:
channels with the basis of the semiconductive material, and
sources and drains with the basis of the semiconductive material on either side of the channels.

14. The method according to claim 6, wherein the semiconductive material is a two-dimensional material chosen from among MX2 transition metal dichalcogenides, with M taken from among molybdenum or tungsten, and X taken from among sulphur, selenium, or tellurium.

15. The method according to claim 6, wherein the spacers are only formed from vertical parts of the continuous layer, without other contribution such as dielectric stoppers made beforehand on flanks of the second layers.
